(19) United States
(12) Patent Application Publication
(10) Pub. No.: US 2026/0324065 A1
(43) Pub. Date: Oct. 15, 2026

(54) SEMICONDUCTOR DEVICE COMPRISING AN INTERMEDIATE INSULATING STRUCTURE AND METHOD OF MANUFACTURING SEMICONDUCTOR DEVICE

(71) Applicant: SAMSUNG ELECTRONICS CO., LTD., Suwon-si (KR)

(72) Inventors: Hyunsoo KIM, Suwon-si (KR); Jaeho JEON, Suwon-si (KR); Donghoon HWANG, Suwon-si (KR)

(73) Assignee: SAMSUNG ELECTRONICS CO., LTD., Suwon-si (KR)

(21) Appl. No.: 19/558,112

(22) Filed: Mar. 5, 2026

(30) Foreign Application Priority Data
Apr. 11, 2025 (KR) 10-2025-0047452

(51) Int. Cl. H10D 84/85; H10D 30/00; H10D 30/01; H10D 64/23; H10D 84/01

(52) U.S. Cl. CPC H10D 84/851; H10D 30/502; H10D 64/254; H10D 64/256; H10D 84/856; H10D 30/0191; H10D 84/0188

(57) ABSTRACT

A semiconductor device is provided having a lower structure, an upper structure, and an intermediate insulating structure positioned between them. The lower structure contains source/drain regions and active layers with a gate structure disposed above the active layers. The upper structure contains source/drain regions and active layers with a gate structure disposed below the active layers, vertically overlapping the lower gate structure. The intermediate insulating structure includes an insulating structure positioned below the upper structure and a barrier structure on the lower structure. The barrier structure has a barrier insulating layer and a barrier pattern disposed above the barrier insulating layer, the barrier pattern surrounding the insulating structure and contacting lower surfaces of the upper source/drain regions.

### CROSS-REFERENCE TO RELATED APPLICATION(S)

This application claims the benefit of priority to Korean Patent Application No. 10-2025-0047452 filed on Apr. 11, 2025 in the Korean Intellectual Property Office, the disclosure of which is incorporated herein by reference in its entirety.

### BACKGROUND

The present inventive concept relates to a semiconductor device and a method of manufacturing the same.

In accordance with demand for a high degree of integration and miniaturization of a semiconductor device, semiconductor elements have also been reduced in size. Accordingly, research into semiconductor devices including stack-type transistors such as complementary field effect transistors (CFET) stacks has been conducted.

### SUMMARY

Aspects of the present inventive concept provide a semiconductor device having improved reliability and improved performance.

According to an aspect of the present inventive concept, there is provided a semiconductor device including a lower structure, an upper structure, and an intermediate insulating structure between the lower structure and the upper structure. The lower structure may include lower source/drain regions spaced apart from each other in a first direction, lower active layers spaced apart from each other in a vertical direction, the lower active layers disposed between the lower source/drain regions, the lower active layers connected to the lower source/drain regions, and a lower gate structure extending in a second direction, perpendicular to the first direction, the lower gate structure including portions respectively disposed above the lower active layers. The upper structure may include upper source/drain regions spaced apart from each other in the first direction, the upper source/drain regions vertically overlapping the lower source/drain regions, upper active layers spaced apart from each other in the vertical direction, the upper active layers disposed between the upper source/drain regions and connected to the upper source/drain regions, the upper active layers vertically overlapping the lower active layers, and an upper gate structure extending in the second direction, the upper gate structure including portions respectively disposed below the upper active layers, the upper gate structure vertically overlapping the lower gate structure. The intermediate insulating structure may include an insulating structure below the upper structure, and a barrier structure including a barrier insulating layer on the lower structure, and a barrier pattern disposed above the barrier insulating layer, the barrier pattern surrounding the insulating structure, the barrier pattern in contact with lower surfaces of the upper source/drain regions.

According to another aspect of the present inventive concept, there is provided a semiconductor device including a first structure, a barrier structure on the first structure, an insulating structure on the barrier structure, and a second structure on the insulating structure. The first structure may include first source/drain regions spaced apart from each other in a first direction, first active layers spaced apart from each other in a vertical direction, the first active layers disposed between the first source/drain regions, the first active layers connected to the first source/drain regions, and a first gate structure extending in a second direction, perpendicular to the first direction, the first gate structure including portions respectively disposed above the first active layers. The second structure may include second source/drain regions spaced apart from each other in the first direction, the second source/drain regions vertically overlapping the first source/drain regions, second active layers spaced apart from each other in the vertical direction, the second active layers disposed between the second source/drain regions and connected to the second source/drain regions, the second active layers vertically overlapping the first active layers, and a second gate structure extending in the second direction, the second gate structure including portions respectively disposed below the second active layers, the second gate structure vertically overlapping the first gate structure. The barrier structure may include a barrier pattern, and a barrier insulating layer surrounding the barrier pattern, on the first structure. The insulating structure may include an insulating pattern, and an insulating liner surrounding the insulating pattern, on the barrier structure.

According to another aspect of the present inventive concept, there is provided a semiconductor device including a lower structure, an upper structure, and an intermediate insulating structure between the lower structure and the upper structure. The lower structure may include lower source/drain regions spaced apart from each other in a first direction, lower active layers spaced apart from each other in a vertical direction, the lower active layers disposed between the lower source/drain regions and connected to the lower source/drain regions, and a lower gate structure extending in a second direction, perpendicular to the first direction, the lower gate structure including portions respectively disposed above the lower active layers. The upper structure may include upper source/drain regions spaced apart from each other in the first direction, the upper source/drain regions vertically overlapping the lower source/drain regions, upper active layers spaced apart from each other in the vertical direction, the upper active layers disposed between the upper source/drain regions and connected to the upper source/drain regions, the upper active layers vertically overlapping the lower active layers, and an upper gate structure extending in the second direction, the upper gate structure including portions respectively disposed below the upper active layers, the upper gate structure vertically overlapping the lower gate structure. The intermediate insulating structure may include a barrier structure disposed on the lower structure, the barrier structure including a barrier pattern and a barrier insulating layer surrounding the barrier pattern, and an insulating structure disposed between the barrier structure and the upper structure, the insulating structure including an insulating pattern and an insulating liner surrounding the insulating pattern. A thickness of the barrier structure may be greater than a thickness of the insulating structure.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor device according to example embodiments;

FIGS. 2A to 2C are schematic cross-sectional views of a semiconductor device according to an example embodiment;

FIGS. 3A to 3C are schematic partially enlarged views of a semiconductor device according to an example embodiment;

FIGS. 4A and 4B are schematic partially enlarged views of a semiconductor device according to an example embodiment;

FIGS. 5A and 5B are schematic partially enlarged views of a semiconductor device according to an example embodiment; and

FIGS. 6A and 6B, FIGS. 7A and 7B, FIGS. 8A to 8C, FIGS. 9A to 9C, FIGS. 10A to 10C, FIGS. 11A to 11C, FIGS. 12A to 12C, FIGS. 13A to 13C, FIGS. 14A to 14C, FIGS. 15A to 15C, FIGS. 16A to 16C, FIGS. 17A to 17C, FIGS. 18A to 18C, FIGS. 19A to 19C, FIGS. 20A to 20C, FIGS. 21A to 21C, FIGS. 22A to 22C, FIGS. 23A to 23C, and 24A to 24C are cross-sectional views of sequential processes in a method of manufacturing a semiconductor device according to an example embodiment of the present inventive concept.

### DETAILED DESCRIPTION

Hereinafter, the terms such as “top,” “upper portion,” “upper surface,” “above,” “bottom,” “lower portion,” “lower surface,” “below,” and “side surface” may be understood as being referred to, based on the drawings, except for being denoted by reference numerals. The terms such as “upper,” “intermediate,” and “lower” may be replaced by other terms, for example, “first,” “second,” and “third,” and may be used to describe components used herein. The terms such as “first,” “second,” and “third” may be used to describe various components, but the above-described components are not limited by the above-described terms, and a “first component” may be referred to as a “second component.”

Hereinafter, preferred example embodiments of the present inventive concept will be described with reference to the accompanying drawings.

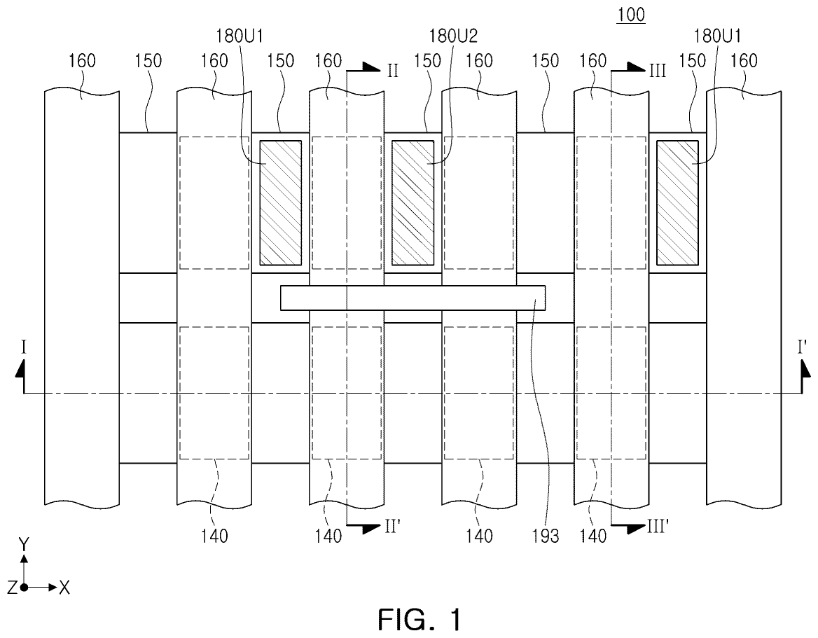

FIG. 1 is a plan view of a semiconductor device according to example embodiments.

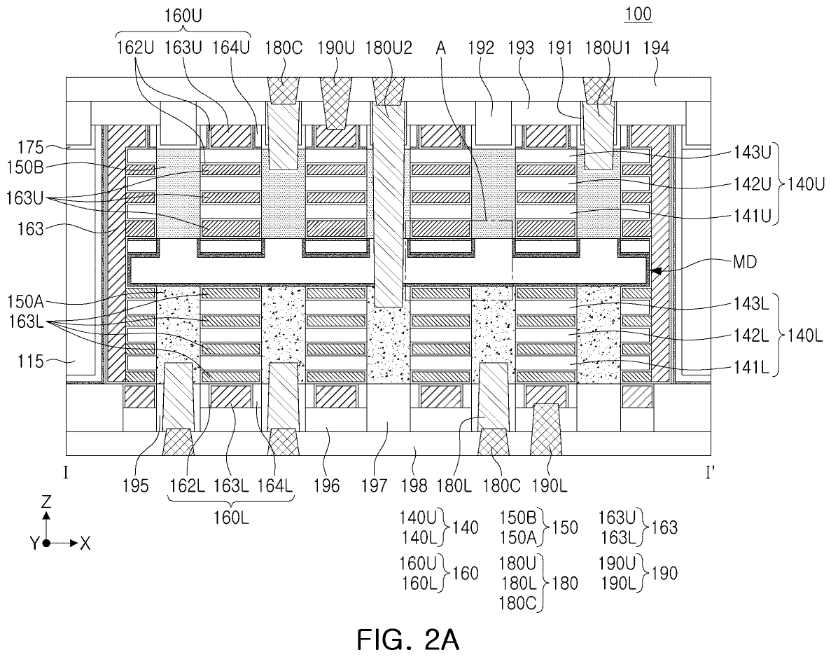

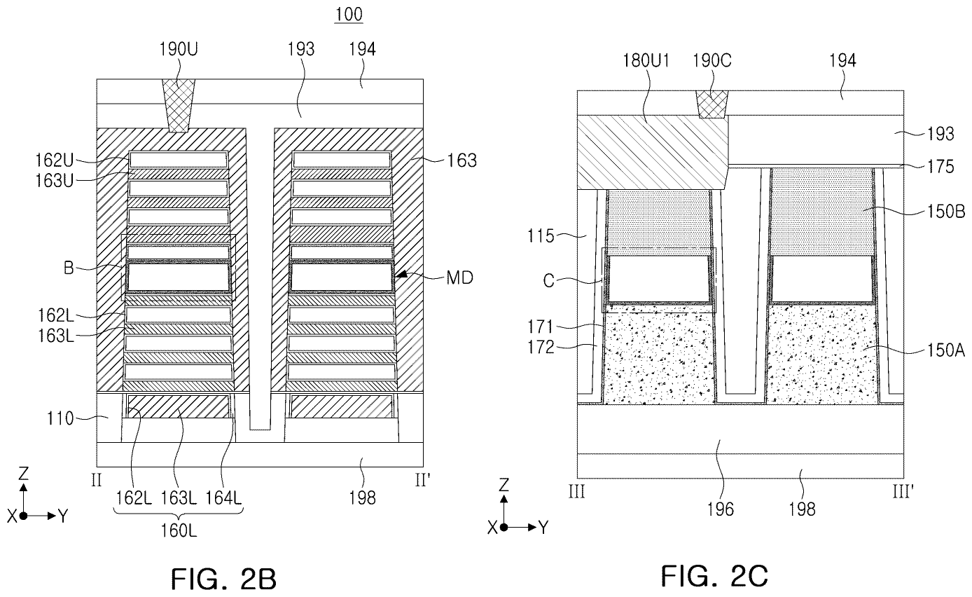

FIGS. 2A to 2C are schematic cross-sectional views of a semiconductor device according to an example embodiment.

FIG. 2A is a cross-sectional view illustrating a region taken along line I-I′ of FIG. 1. FIG. 2B is a cross-sectional view of a region taken along line II-II′ of FIG. 1. FIG. 2C is a cross-sectional view of a region taken along line III-III′ of FIG. 1.

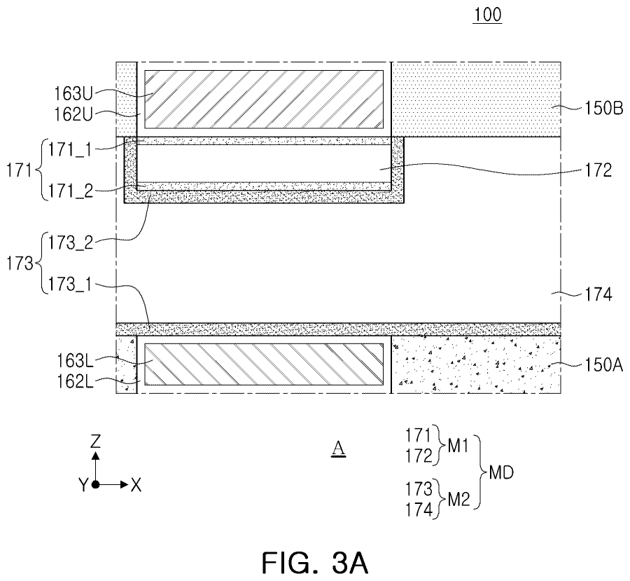

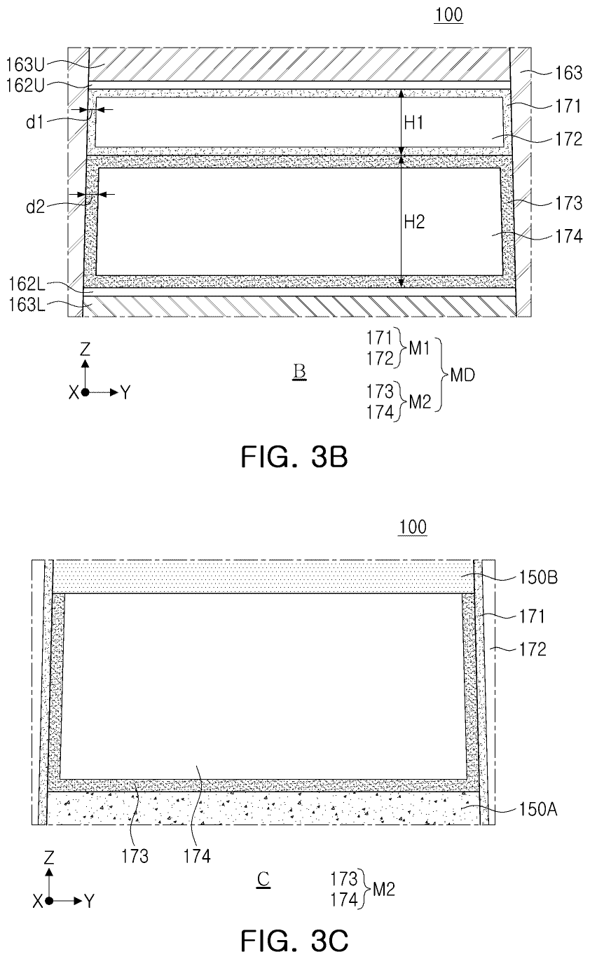

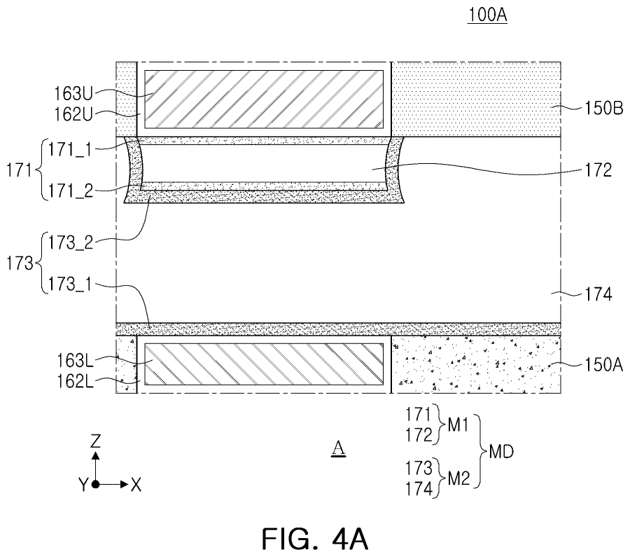

FIGS. 3A to 3C are schematic partially enlarged views of a semiconductor device according to an example embodiment. FIG. 3A is a partially enlarged view of region “A” of FIG. 2A, FIG. 3B is a partially enlarged view of region “B” of FIG. 2B, and FIG. 3C is a partially enlarged view of region “C” of FIG. 2C.

Referring to FIGS. 1 to 3C, a semiconductor device 100 may include a lower structure, an intermediate insulating structure MD on the lower structure, and an upper structure on the intermediate insulating structure MD. The semiconductor device 100 may further include a contact structure 180, a gate contact structure 190, and upper and lower interlayer insulating layers 191, 192, 193, 194, 195, 196, 197, and 198.

As used herein, a first direction may refer to an X-direction, and a second direction may refer to a Y-direction, but the present inventive concept is not limited thereto. For example, in an example embodiment, the first direction may refer to the Y-direction, and the second direction may refer to the X-direction.

As used herein, a “first structure” and a “second structure” described in the claims may respectively be referred to as a “lower structure” and an “upper structure,” a “first gate structure” and “first source/drain regions” may be referred to as a “lower gate structure” and “lower source/drain regions,” and a “second gate structure” and “second source/drain regions” may be referred to as an “upper gate structure” and “upper source/drain regions.”

The lower structure may include a lower gate structure 160L extending in a second direction Y, lower channel layers 140L spaced apart from each other in a third direction Z, perpendicular to first and second directions X and Y, the lower channel layers 140L surrounded by the lower gate structure 160L, and lower source/drain regions 150A disposed on at least one side of the lower channel layers 140L, the lower source/drain regions 150A connected to the lower channel layers 140L. In an example embodiment, the lower channel layers 140L may be referred to as lower active layers.

The upper structure may include an upper gate structure 160U disposed on the lower gate structure 160L and the intermediate insulating structure MD, the upper gate structure 160U extending in the second direction Y, upper channel layers 140U spaced apart from each other in the third direction Z, the upper channel layers 140U surrounded by the upper gate structure 160U, and upper source/drain regions 150B disposed on at least one side of the upper channel layers 140U, the upper source/drain regions 150B connected to the upper channel layers 140U. In an example embodiment, the upper channel layers 140U may be referred to as upper active layers.

The lower gate structure 160L and the upper gate structure 160U may be collectively referred to as a gate structure 160. The lower channel layers 140L and the upper channel layers 140U may be collectively referred to as channel layers 140. The lower source/drain regions 150A and the upper source/drain regions 150B may be collectively referred to as source/drain regions 150.

The semiconductor device 100 may include transistors having a multi-bridge channel FET (MBCFET™) structure, which is a gate-all-around field-effect transistor. According to an example embodiment, the semiconductor device may include transistors having a complementary FET (CFET) structure.

The gate structure 160 may include the lower gate structure 160L and the upper gate structure 160U.

The gate structure 160 may be disposed on a channel structure 140 to intersect the channel structure 140 and extend in the second direction, for example, the Y-direction.

The lower gate structure 160L may include a lower gate electrode 163L, a lower gate dielectric layer 162L between the lower gate electrode 163L and first to third lower channel layers 141L, 142L, and 143L, and lower gate spacer layers 164L on side surfaces of the lower gate electrode 163L. The lower gate structure 160L may extend in the second direction Y, perpendicular to the first direction X, and may include portions respectively disposed above the lower channel layers 140L. The lower gate electrode 163L may include a portion disposed above the first to third lower channel layers 141L, 142L, and 143L.

The upper gate structure 160U may include an upper gate electrode 163U, an upper gate dielectric layer 162U between the upper gate electrode 163U and first to third upper channel layers 141U, 142U, and 143U, and upper gate spacer layers 164U on side surfaces of the upper gate electrode 163U. The upper gate structure 160U may vertically overlap the lower gate structure 160L. The upper gate structure 160U may extend in the second direction Y, and may include portions respectively disposed below the upper channel layers 140U. The gate spacer layers 164U may be disposed on both sides of the upper gate electrode 163U, on the upper channel layers 140U. The upper gate electrode 163U may include a portion disposed below the first to third upper channel layers 141U, 142U, and 143U.

The lower gate dielectric layer 162L may be disposed between the intermediate insulating structure MD and the lower gate electrode 163L and between the lower channel layers 140L and the lower gate electrode 163L.

The upper gate dielectric layer 162U may be disposed between the intermediate insulating structure MD and the upper gate electrode 163U and between the upper channel layers 140U and the upper gate electrode 163U.

The lower gate dielectric layer 162L and the upper gate dielectric layer 162U may include oxide, nitride, or a high-κ material. The high-κ material may refer to a dielectric material having a dielectric constant higher than that of a silicon oxide film (SiO₂). The high-κ material may be one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSixOy), hafnium oxide (HfO₂), hafnium silicon oxide (HfSixOy), lanthanum oxide (La₂O₃), lanthanum aluminum oxide (LaAlxOy), lanthanum hafnium oxide (LaHfxOy), hafnium aluminum oxide (HfAlxOy), and praseodymium oxide (Pr₂O₃). In an example embodiment, the lower gate dielectric layer 162L and the upper gate dielectric layer 162U may be formed as multilayer films.

The lower gate electrode 163L may be disposed below an intermediate insulating structure MD to fill spaces between first to third lower channel layers 141L, 142L, and 143L, and to extend onto the lower channel layer 140L. The lower gate electrode 163L may be spaced apart from the first to third lower channel layers 141L, 142L, and 143L by the lower gate dielectric layers 162L.

The upper gate electrode 163U may be disposed above the intermediate insulating structure MD to fill spaces between first to third upper channel layers 141U, 142U, and 143U, and to extend onto the upper channel layers 140U. The upper gate electrode 163U may be spaced apart from the first to third upper channel layers 141U, 142U, and 143U by the upper gate dielectric layer 162U.

The lower gate electrode 163L and the upper gate electrode 163U may include a conductive material, for example, a metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. In some example embodiments, the lower gate electrode 163L and the upper gate electrode 163U may be formed as two or more multilayers. According to an example embodiment, the lower gate electrode 163L and the upper gate electrode 163U may be formed of a material having a proper work function in consideration of a desired threshold voltage. The lower gate electrode 163L may include an N-type work function layer, and the upper gate electrode 163U may include a P-type work function layer, but the present inventive concept is not limited thereto. According to another example embodiment, the lower gate electrode 163L may include a P-type work function layer, and the upper gate electrode 163U may include an N-type work function layer.

The lower gate spacer layers 164L may be disposed on both side surfaces of the lower gate electrode 163L, below the lower channel layers 140L. The lower gate spacer layers 164L may insulate the lower source/drain regions 150A and the lower gate electrode 163L from each other. In some example embodiments, the lower gate spacer layers 164L may have a multilayer structure. The lower gate spacer layers 164L may be formed of oxide, nitride, and oxynitride, and particularly may be formed of a low-κ dielectric film.

The upper gate spacer layers 164U may insulate the upper source/drain regions 150B and the upper gate electrode 163U from each other. In some example embodiments, the upper gate spacer layers 164U may have a multilayer structure. The upper gate spacer layers 164U may be formed of oxide, nitride, and oxynitride, and particularly may be formed of a low-κ dielectric film.

The channel structure 140 may include lower channel layers 140L and upper channel layers 140U.

The lower channel layers 140L may include first to third lower channel layers 141L, 142L, and 143L, which are a plurality of channel layers sequentially disposed and spaced apart from each other in the third direction, for example, in a Z-direction, perpendicular to the first and second directions X and Y. The first to third lower channel layers 141L, 142L, and 143L may be disposed between the lower source/drain regions 150A, and may be connected to the lower source/drain regions 150A.

The upper channel layers 140U may include first to third upper channel layers 141U, 142U, and 143U, which are a plurality of channel layers sequentially disposed on the intermediate insulating structure MD and spaced apart from each other in a direction, perpendicular to an upper surface of the intermediate insulating structure MD, for example, in the Z-direction. The first to third upper channel layers 141U, 142U, and 143U may be connected to the upper source/drain regions 150B. The upper channel layers 140U may vertically overlap the lower channel layers 140L.

The first to third upper channel layers 141U, 142U, and 143U may have a width in the first direction X that is substantially the same as or similar to that of the upper gate structure 160U. The first to third lower channel layers 141L, 142L, and 143L may have a width in the first direction X that is substantially the same as or similar to that of the lower gate structure 160L.

The first to third lower channel layers 141L, 142L, and 143L and the first to third upper channel layers 141U, 142U, and 143U may be formed of a semiconductor material and may include, for example, at least one of silicon (Si), silicon germanium (SiGe), or germanium (Ge). The number and shape of the first to third lower channel layers 141L, 142L, and 143L and the first to third upper channel layers 141U, 142U, and 143U may be changed in various manners in example embodiments.

The source/drain regions 150 may include lower source/drain regions 150A and upper source/drain regions 150B on the lower source/drain regions 150A. The upper source/drain regions 150B may be spaced apart from each other in the first direction X, and may vertically overlap the lower source/drain regions 150A.

The source/drain regions 150 may be provided as a source region or a drain region of a transistor. The source/drain regions 150 may be disposed on both sides of the gate structure 160. The source/drain regions 150 may be disposed to cover side surfaces of each of the lower channel layers 140L and the upper channel layers 140U.

The source/drain regions 150 may be a semiconductor layer including silicon (Si) and/or silicon germanium (SiGe). The source/drain regions 150 may include different types and/or concentrations of impurities. The lower source/drain regions 150A and the upper source/drain regions 150B may have different conductivity types. According to an example embodiment, the lower source/drain regions 150A may include N-type doped silicon (Si), and the upper source/drain regions 150B may include P-type doped silicon germanium (SiGe). However, the present inventive concept is not limited thereto. According to another example embodiment, the lower source/drain regions 150A may include P-type doped silicon germanium (SiGe), and the upper source/drain regions 150B may include N-type doped silicon (Si). In example embodiments, the source/drain regions 150 may include a plurality of regions having different concentrations of elements and/or dopant elements.

The intermediate insulating structure MD may include an insulating structure M1 and a barrier structure M2 disposed between the lower structure and the upper structure. The insulating structure M1 and the barrier structure M2 may be described with reference to FIGS. 3A, 3B, and 3C.

Referring to FIG. 3A, the insulating structure M1 may be disposed below the upper structure. The insulating structure M1 may include an insulating liner 171 including an upper portion 171_1 on a lower surface of the upper structure and a lower portion 171_2 below the upper portion 171_1, and an insulating pattern 172 between the upper and lower portions 171_1 and 171_2 of the insulating liner 171. Side surfaces of the insulating liner 171 and the insulating pattern 172 may be aligned with each other. The upper portion 171_1 may be in contact with the upper gate dielectric layer 162U. A side surface of the insulating structure M1 may be aligned with a side surface of the upper gate dielectric layer 162U.

Referring to FIG. 3A, the barrier structure M2 may include a barrier insulating layer 173 including a first portion 173_1 extending in the first direction X on an upper surface of the lower structure and a second portion 173_2 surrounding a lower surface and a side surface of the insulating structure M1, and a barrier pattern 174 on the barrier insulating layer 173. Referring to FIG. 3A, the barrier pattern 174 may be disposed to surround the insulating structure M1. The first portion 173_1 may be in contact with upper surfaces of the lower source/drain regions 150A and an upper surface of the lower gate dielectric layer 162L. The second portion 173_2 may be in contact with at least a portion of lower surfaces of the upper source/drain regions 150B. At least a portion of the barrier pattern 174 may be in contact with a portion of the lower surfaces of the upper source/drain regions 150B.

Referring to FIG. 3B, the insulating structure M1 may be disposed between the upper structure and the barrier structure M2. The insulating liner 171 may surround an upper surface, a lower surface, and side surfaces of the insulating pattern 172. The insulating liner 171 may be in contact with the upper gate dielectric layer 162U. A side surface of the insulating structure M1 may be aligned with a side surface of the upper gate dielectric layer 162U. In an example embodiment, a height H1 of the insulating structure M1 in the third direction Z may be about 10 nm or less. In an example embodiment, the height H1 of the insulating structure M1 in the third direction Z may be in a range of about 5 nm to about 10 nm. In an example embodiment, the height H1 of the insulating structure M1 in the third direction Z may be in a range of about 8 nm to about 10 nm.

Referring to FIG. 3B, the barrier structure M2 may be disposed between the lower structure and the insulating structure M1. The barrier insulating layer 173 may surround an upper surface, a lower surface, and side surfaces of the barrier pattern 174. The barrier insulating layer 173 may be in contact with the lower gate dielectric layer 162L. A side surface of the barrier structure M2 may be aligned with a side surface of the insulating structure M1 and a side surface of the lower gate dielectric layer 162L. In an example embodiment, a height H2 of the barrier structure M2 in the third direction Z may be greater than the height H1 of the insulating structure M1 in the third direction Z. From another perspective, the insulating structure M1 may be disposed on an upper end of the intermediate insulating structure MD. Here, the height H2 of the barrier structure M2 in the third direction Z may refer to a height of the barrier structure M2 between the lower structure and the insulating structure M1.

Referring to FIG. 3B, a thickness d1 of the insulating pattern 172 may be less than a thickness d2 of the barrier pattern 174. A relationship between the thickness d1 of the insulating pattern 172 and the thickness d2 of the barrier pattern 174 may be applied to the semiconductor devices, illustrated in FIGS. 3A and 3C, in substantially the same manner. A width of the insulating pattern 172 in the second direction Y may be greater than a width of the barrier pattern 174 in the second direction Y. The width of the insulating pattern 172 in the second direction Y being greater than the width of the barrier pattern 174 in the second direction Y may be understood to be due to the thickness d1 of the insulating pattern 172 being less than the thickness d2 of the barrier pattern 174.

Referring to FIG. 3C, the barrier insulating layer 173 may surround a lower surface and side surfaces of the barrier pattern 174, between the lower and upper source/drain regions 150A and 150B. The insulating liner 171 may be disposed on the barrier insulating layer 173, and the insulating pattern 172 may be disposed on the insulating liner 171.

The insulating structure M1 and the barrier structure M2 may include an insulating material. For example, the insulating structure M1 and the barrier structure M2 may include silicon oxide, silicon nitride, silicon oxynitride, or silicon oxycarbonitride. In an example embodiment, the insulating liner 171 may include silicon nitride. In an example embodiment, the insulating pattern 172 may include silicon oxycarbonitride. In an example embodiment, the barrier insulating layer 173 may include silicon nitride. In an example embodiment, the barrier pattern 174 may include silicon oxide.

The contact structure 180 may include a lower contact structure 180L electrically connected to the lower source/drain regions 150A, and an upper contact structure 180U electrically connected to the upper source/drain regions 150B.

The contact structure 180 may be disposed on the source/drain regions 150. In some example embodiments, the contact structure 180 may be disposed to have a greater length in the second direction Y than lengths of the source/drain regions 150 in the second direction Y. The contact structure 180 may be disposed to recess the source/drain regions 150 to a predetermined depth.

The lower contact structure 180L may pass through at least a portion of an interlayer insulating layer 195, may be in contact with the lower source/drain regions 150A, and may apply an electrical signal to the lower source/drain regions 150A.

The upper contact structure 180U may include a first upper contact structure 180U1 and a second upper contact structure 180U2. The first upper contact structure 180U1 may pass through at least a portion of an interlayer insulating layer 191, may be in contact with a first upper source/drain region, among the upper source/drain regions 150B, and may apply an electrical signal to the first upper source/drain region. The second upper contact structure 180U2 may pass through at least a portion of the interlayer insulating layer 191, a second upper source/drain region, among the upper source/drain regions 150B, and the intermediate insulating structure MD, may be in contact with a lower source/drain region 150A, and may apply an electrical signal to the lower source/drain region 150A. The second upper contact structure 180U2 may include a conductive material layer and a barrier layer on an outer surface of the conductive material layer.

The contact structure 180 may further include a contact via structure 180C on the upper and lower contact structures 180U and 180L. For example, at least a portion of the contact via structure 180C may be disposed above the upper contact structure 180U, and a portion of the contact via structure 180C may be disposed below the lower contact structure 180L.

The gate contact structure 190 may include a lower gate contact structure 190L and an upper gate contact structure 190U. The lower gate contact structure 190L may be in contact with the lower gate electrode 163L, and the upper gate contact structure 190U may be in contact with the upper gate electrode 163U. The gate contact structure 190 may have a shape and a material similar to those of the contact structure 180, but the present inventive concept is not limited thereto. According to an example embodiment, each of the lower and upper gate contact structures 190L and 190U may include a conductive material layer and a barrier layer on an outer surface of the conductive material layer. An upper surface of the gate contact structure 190 may be substantially coplanar with an upper surface of the contact via structure 180C.

The first to fourth upper interlayer insulating layers 191, 192, 193, and 194 may include, for example, at least one of oxide, nitride, oxynitride, and a low-κ dielectric.

The first to third upper interlayer insulating layers 191, 192, and 193 may be disposed to cover the upper source/drain regions 150B and the upper gate structure 160U. The fourth upper interlayer insulating layer 194 may cover the first to third upper interlayer insulating layers 191, 192, and 193.

The first to fourth lower interlayer insulating layers 195, 196, 197, and 198 may include, for example, at least one of oxide, nitride, oxynitride, and a low-κ dielectric.

The first to third lower interlayer insulating layers 195, 196, and 197 may be disposed to cover the lower source/drain regions 150A and the lower gate structure 160L. The fourth lower interlayer insulating layer 198 may cover the first to third lower interlayer insulating layers 195, 196, and 197.

The semiconductor device 100 of the present inventive concept may further include interconnection structures, respectively disposed above the contact via structure 180C and the gate contact structure 190. For example, the interconnection structures may be defined to include a first interconnection on the contact via structure 180C and a second interconnection on the gate contact structure 190.

In the present inventive concept, the intermediate insulating structure MD having a predetermined thickness or less may be disposed between the lower and upper structures, thereby preventing degradation that may occur between the intermediate insulating structure MD and the lower structure and between the intermediate insulating structure MD and the upper structure. In the present inventive concept, the degradation may include degradation due to a lattice difference between adjacent structures. For example, to minimize and prevent the degradation, a thickness of the insulating structure M1 of the intermediate insulating structure MD of the present inventive concept may be less than a thickness of the barrier structure M2 of the intermediate insulating structure MD. The thickness of the insulating structure M1 may be about 10 nm or less, for example, the thickness of the insulating structure M1 may be in a range from about 5 nm to about 10 nm.

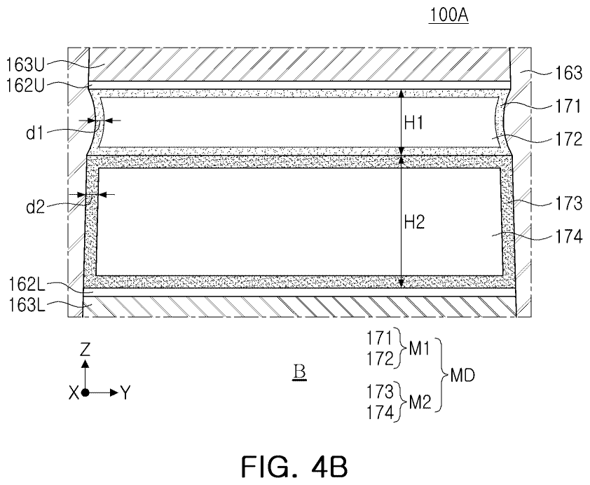

FIGS. 4A and 4B are schematic partially enlarged views of a semiconductor device 100A according to an example embodiment. FIG. 4A is a partially enlarged view of region “A” of FIG. 2A, and FIG. 4B is a partially enlarged view of region “B” of FIG. 2B.

Referring to FIGS. 4A and 4B, the semiconductor device 100A may be substantially the same as or similar to those described with reference to FIGS. 1 to 3C, except that the semiconductor device 100A includes an insulating structure M1 having a curved side surface.

In the present example embodiment, the insulating structure M1 may have a side surface having a curved shape. For example, the side surface of the insulating structure M1 may have a concave shape toward the center of the insulating structure M1. Accordingly, at least a portion of the barrier insulating layer 173 may also have a curved cross-sectional shape (see FIG. 4A). For example, a portion of the second portion 173_2 of the barrier insulating layer 173 that is in contact with the side surface of the insulating structure M1 may have a curved cross-sectional shape.

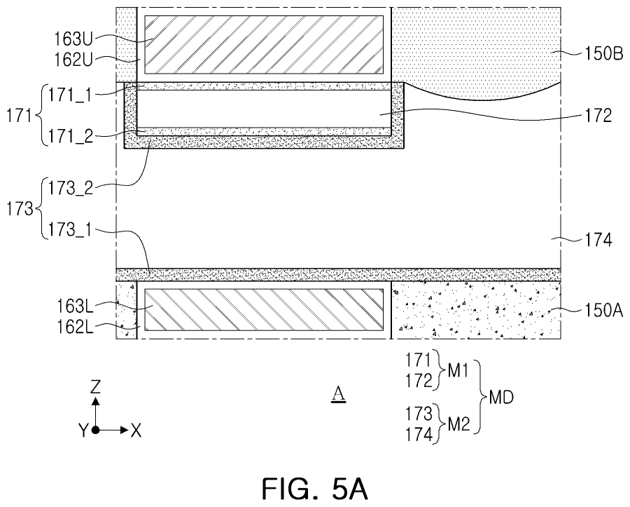

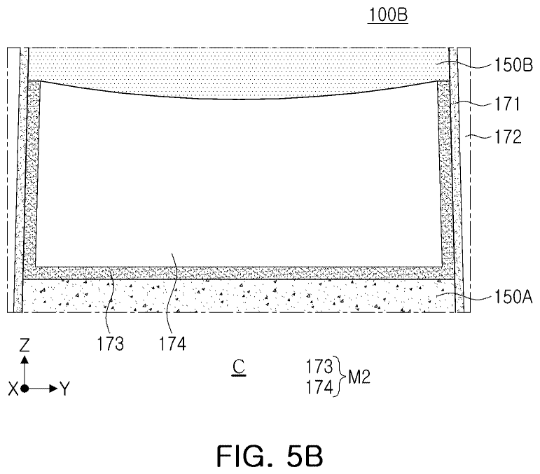

FIGS. 5A and 5B are schematic partially enlarged views of a semiconductor device 100B according to an example embodiment. FIG. 5A is a partially enlarged view of region “A” of FIG. 2A, and FIG. 5B is a partially enlarged view of region “C” of FIG. 2C.

Referring to FIGS. 5A and 5B, the semiconductor device 100B may be substantially the same as or similar to those described with reference to FIGS. 1 to 3C, except that a barrier pattern 174 having a recessed portion toward a lower structure is included.

In the present example embodiment, at least a portion of an upper surface of a barrier pattern 174 of a barrier structure M2 may have a recessed shape toward a lower structure. The recessed portion may vertically overlap lower and upper source/drain regions 150A and 150B. In the present example embodiment, lower surfaces of the upper source/drain regions 150B may have a convex shape toward the lower structure.

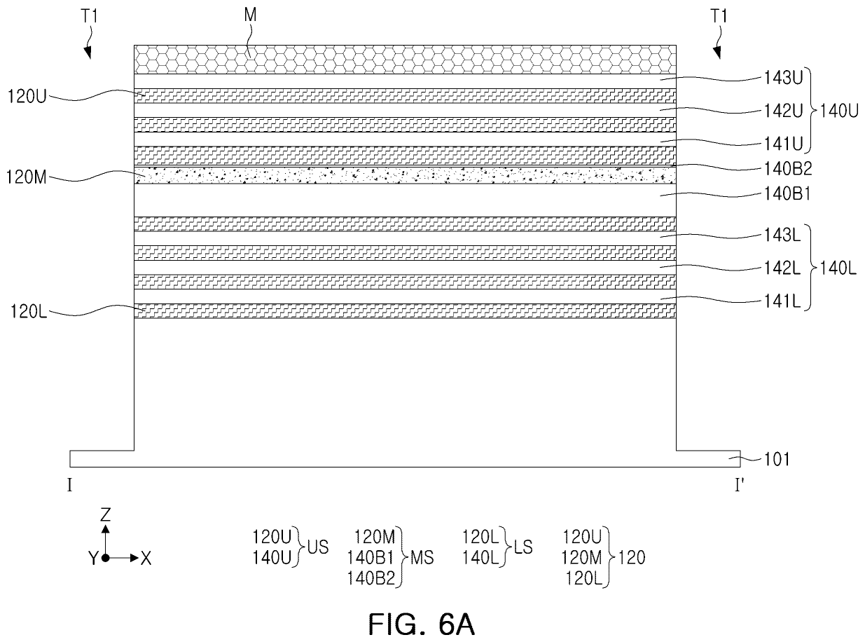

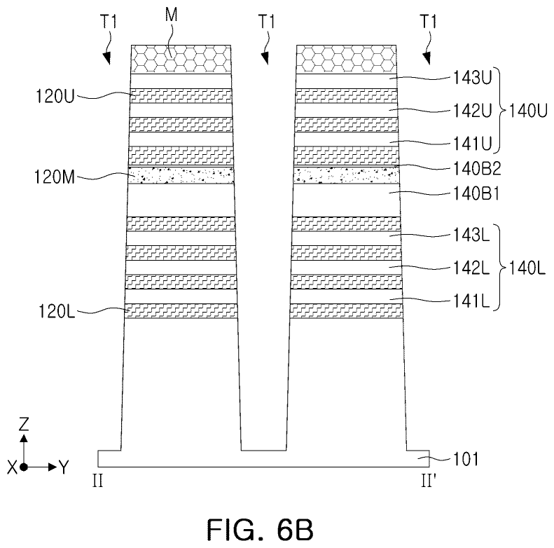

FIGS. 6A and 6B, FIGS. 7A and 7B, FIGS. 8A to 8C, FIGS. 9A to 9C, FIGS. 10A to 10C, FIGS. 11A to 11C, FIGS. 12A to 12C, FIGS. 13A to 13C, FIGS. 14A to 14C, FIGS. 15A to 15C, FIGS. 16A to 16C, FIGS. 17A to 17C, FIGS. 18A to 18C, FIGS. 19A to 19C, FIGS. 20A to 20C, FIGS. 21A to 21C, FIGS. 22A to 22C, FIGS. 23A to 23C, and 24A to 24C are cross-sectional views of sequential processes in a method of manufacturing a semiconductor device according to an example embodiment of the present inventive concept.

Referring to FIGS. 6A and 6B, a lower stack LS, an intermediate stack MS on the lower stack LS, and an upper stack US on the intermediate stack MS may be sequentially formed on a substrate 101.

The substrate 101 may have upper surfaces extending in a first direction X and a second direction Y. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a SeOI (SEM) layer, or the like.

The lower stack LS may include lower sacrificial layers 120L and lower channel layers 140L that are alternately stacked. The intermediate stack MS may include a first buffer layer 140B1, an intermediate sacrificial layer 120M, and a second buffer layer 140B2 that are alternately stacked. The upper stack US may include upper sacrificial layers 120U and upper channel layers 140U that are alternately stacked. In an example embodiment, the lower, intermediate, and upper sacrificial layers 120L, 120M, and 120U may be collectively referred to as sacrificial layers 120.

The sacrificial layers 120 may have etching selectivity with respect to the first to third lower channel layers 141L, 142L, and 143L, the first and second buffer layers 140B1, 140B2, and the first to third upper channel layers 141U, 142U, and 143U. In an example embodiment, the first to third lower channel layers 141L, 142L, and 143L, the first and second buffer layers 140B1 and 140B2, and the first to third upper channel layers 141U, 142U, and 143U may include silicon (Si), and the sacrificial layers 120 may include silicon germanium (SiGe).

A first germanium concentration of the intermediate sacrificial layer 120M may be different from a second germanium concentration of each of the upper and lower sacrificial layers 120U and 120L. For example, the first germanium concentration of the intermediate sacrificial layer 120M may be greater than the second germanium concentration of each of the upper and lower sacrificial layers 120U and 120L.

In an example embodiment, the first germanium concentration may be about 20 at % to 60 at %.

In an example embodiment, the first germanium concentration may be about 30 at % to 50 at %.

In an example embodiment, the first germanium concentration may be about 35 to 45 at %.

In an example embodiment, the second germanium concentration may be about 15 at % to 20 at %.

In the present inventive concept, the intermediate sacrificial layer 120M may be configured as a single layer. From another perspective, the intermediate sacrificial layer 120M may not include a plurality of layers.

In the present inventive concept, the intermediate sacrificial layer 120M may be disposed between the first and second buffer layers 140B1 and 140B2. Accordingly, the intermediate sacrificial layer 120M may not be in contact with the channel layers (for example, 140U and 140L). As a result, degradation that may occur from a lattice difference between the intermediate sacrificial layer 120M and the channel layers (for example, 140U and 140L) may be minimized or prevented.

The sacrificial layers 120, the first to third lower channel layers 141L, 142L, and 143L, the first and second buffer layers 140B1 and 140B2, and the first to third upper channel layers 141U, 142U, and 143U may be formed by performing an epitaxial growth process using the substrate 101 as a seed. A thickness of the first buffer layer 140B1 may be greater than a thickness of each of the first to third lower and upper channel layers 141L, 142L, 143L, 141U, 142U, and 143U. A thickness of the second buffer layer 140B2 may be less than the thickness of each of the first to third lower and upper channel layers 141L, 142L, 143L, 141U, 142U, and 143U. The thickness of the second buffer layer 140B2 may be less than a thickness of the intermediate sacrificial layer 120M, and the thickness of the first buffer layer 140B1 may be greater than the thickness of the intermediate sacrificial layer 120M. The thickness of the intermediate sacrificial layer 120M may be about 10 nm or less. For example, the thickness of the intermediate sacrificial layer 120M may be about 5 nm to about 10 nm.

A mask M may be formed on the upper stack US. Thereafter, using the mask M, trenches T1, removing at least a portion of the lower stack LS, the intermediate stack MS, and the upper stack US and exposing an upper surface of the substrate 101, may be formed.

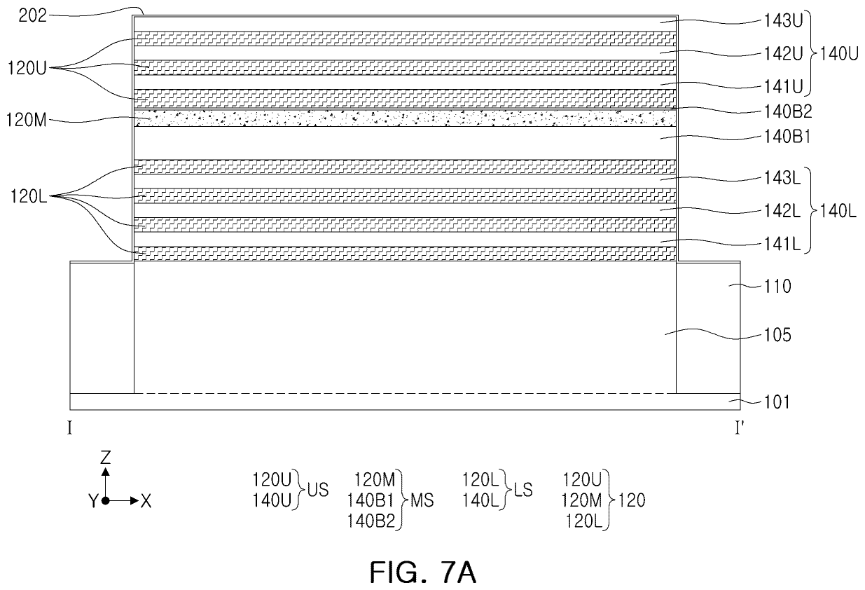

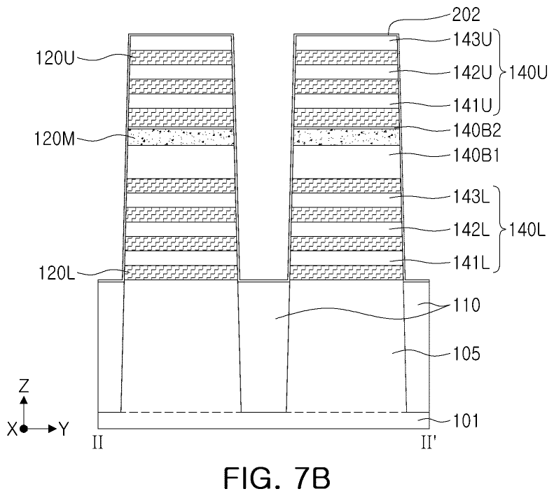

Referring to FIGS. 7A and 7B, an isolation layer 110, defining an active region 105, may be formed in the trenches T1, and an etch stop layer 202, covering the upper stack US and the isolation layer 110, may be formed.

The isolation layer 110 may be formed using, for example, a shallow trench isolation (STI) process. The isolation layer 110 may expose an upper surface of the active region 105, and may partially expose an upper portion of the active region 105. The isolation layer 110 may be formed of an insulating material. The isolation layer 110 may be, for example, oxide, nitride, or a combination thereof.

The etch stop layer 202 may be formed to conformally cover an upper surface of the isolation layer 110, a side surface of the lower stack LS, a side surface of the intermediate stack MS, and a side surface and an upper surface of the upper stack US.

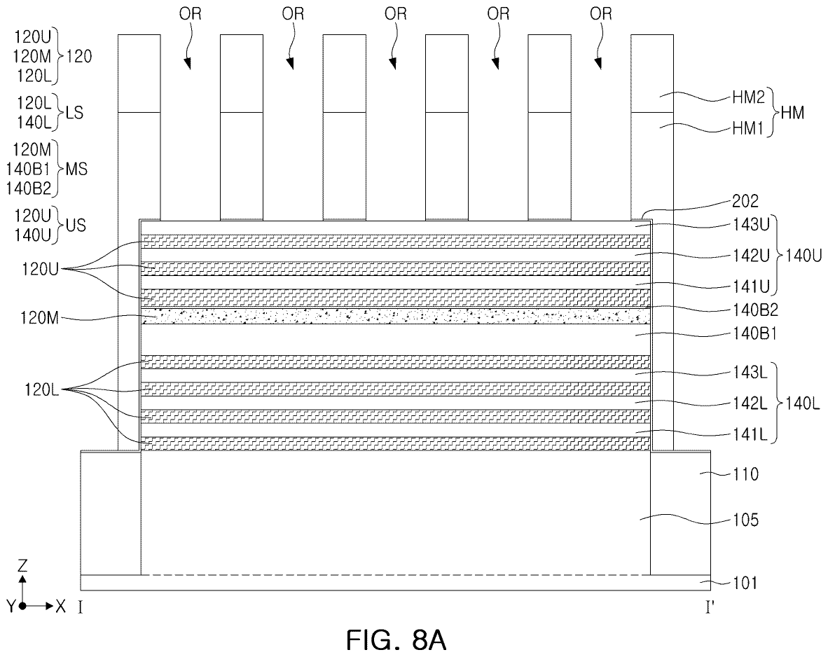

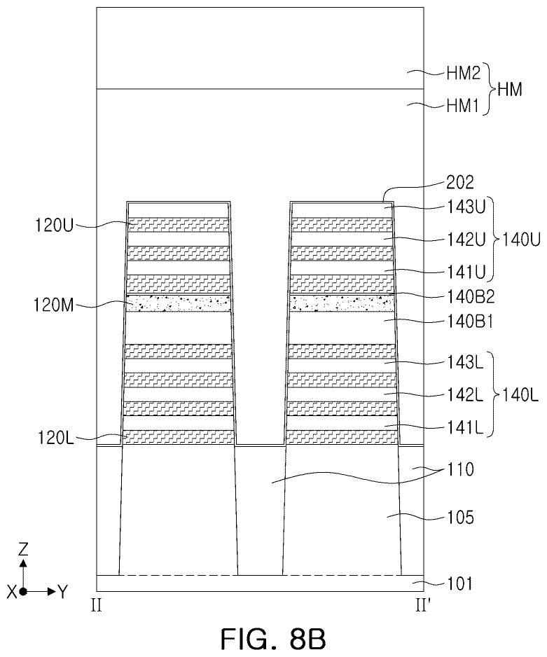

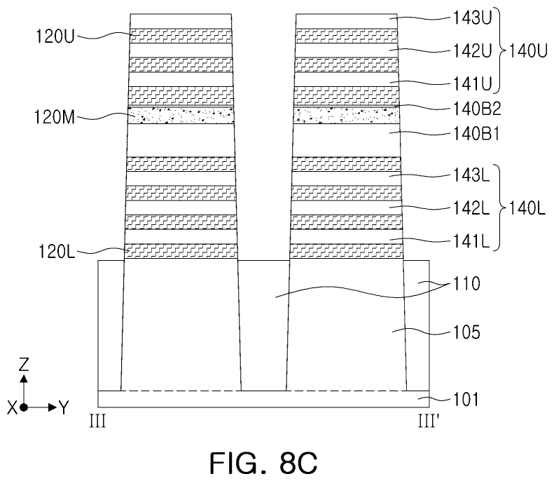

Referring to FIGS. 8A to 8C, a mask HM may be formed on the etch stop layer 202, and an open region OR passing through the etch stop layer 202, the open region OR exposing at least a portion of the upper stack US may be formed.

The mask HM may include a hard mask. The mask HM may include a plurality of layers including a first layer HM1 and a second layer HM2 on the first layer HM1. At least a portion of an uppermost upper channel layer 143U, among the upper channel layers 140U, may be exposed by the open region OR.

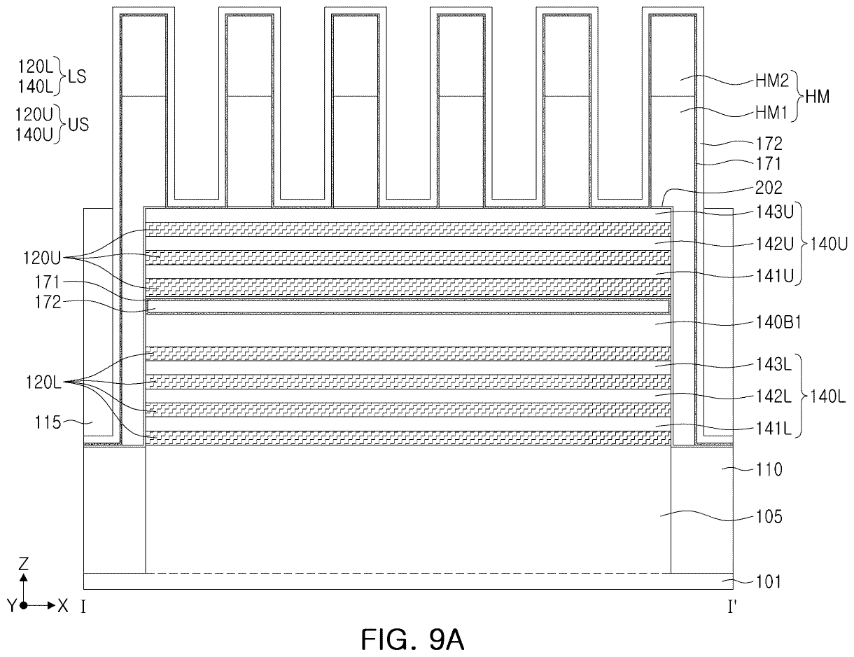

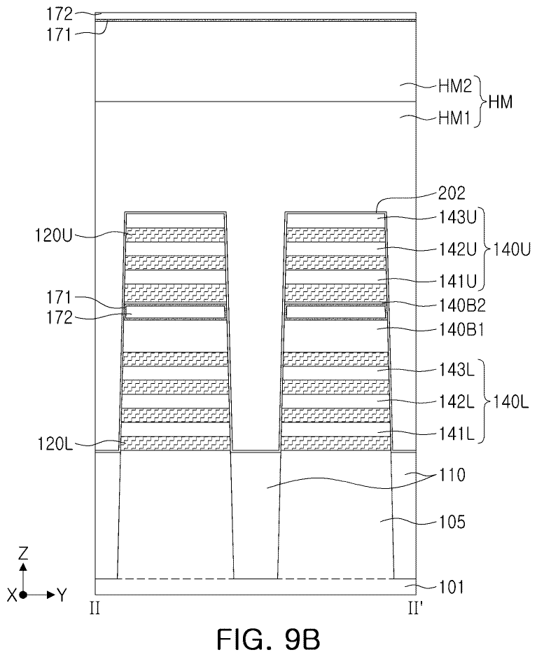

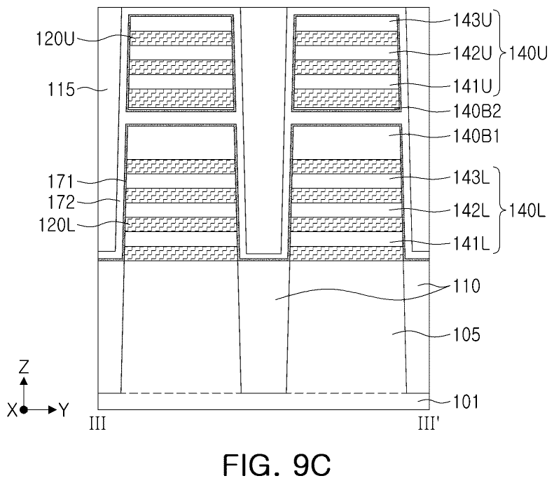

Referring to FIGS. 9A to 9C, the intermediate sacrificial layer 120M may be selectively removed, and an insulating liner 171 and an insulating pattern 172 may be formed.

The intermediate sacrificial layer 120M may be selectively removed due to etching selectivity. Subsequently, the insulating liner 171 and the insulating pattern 172, covering the mask HM, may be formed. At least a portion of each of the insulating liner 171 and the insulating pattern 172 may fill a portion from which the intermediate sacrificial layer 120M has been removed. Subsequently, a molded structure 115 may be formed and partially removed so as to have an upper surface substantially the same as the upper surface of the upper stack US.

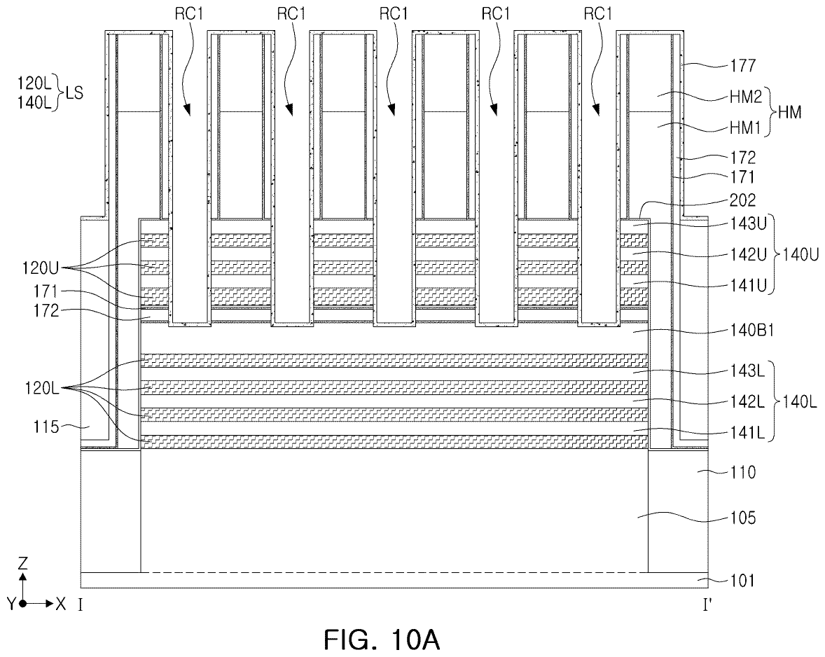

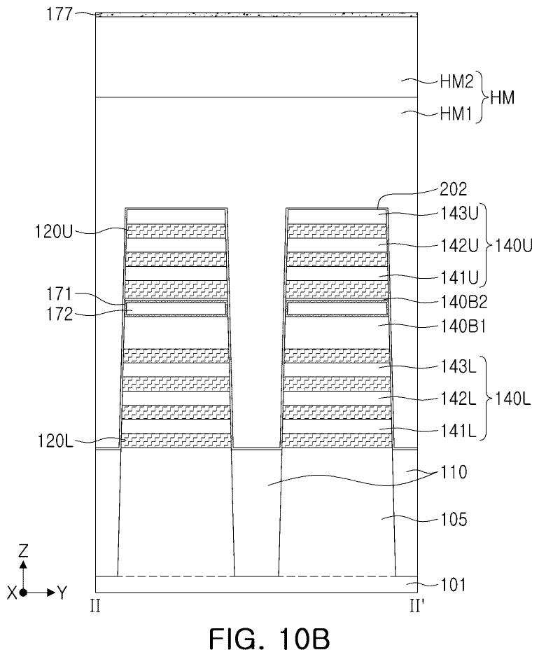

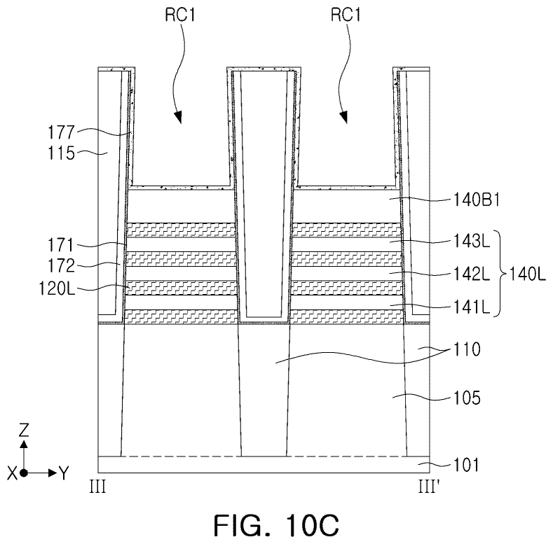

Referring to FIGS. 10A to 10C, a first recess portion RC1 passing through the upper stack US, the insulating liner 171, and the insulating pattern 172, the first recess portion RC1 exposing the second buffer layer 140B2 may be formed. An insulating layer 177 covering an outer surface of the first recess portion RC1 may be formed.

An insulating structure M1 including the remaining insulating liner 171 and insulating pattern 172 may be defined by the first recess portion RC1.

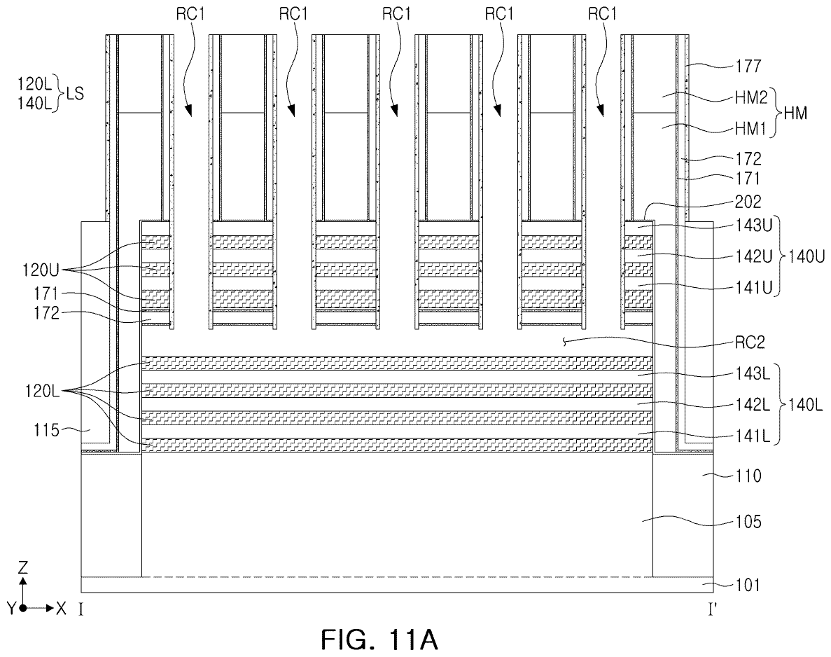

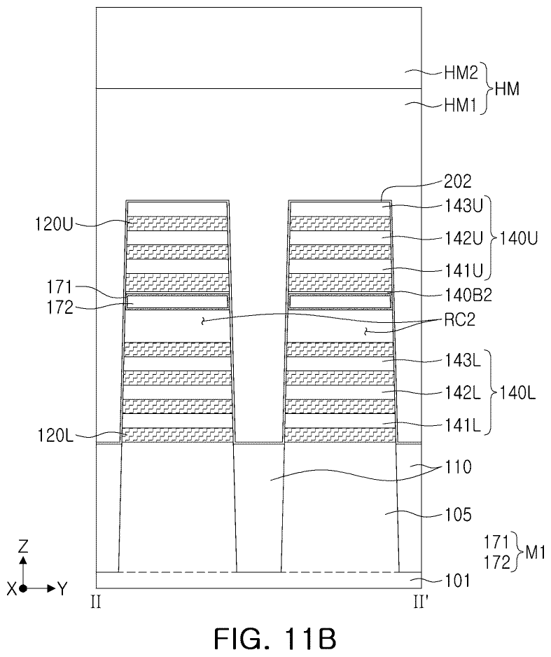

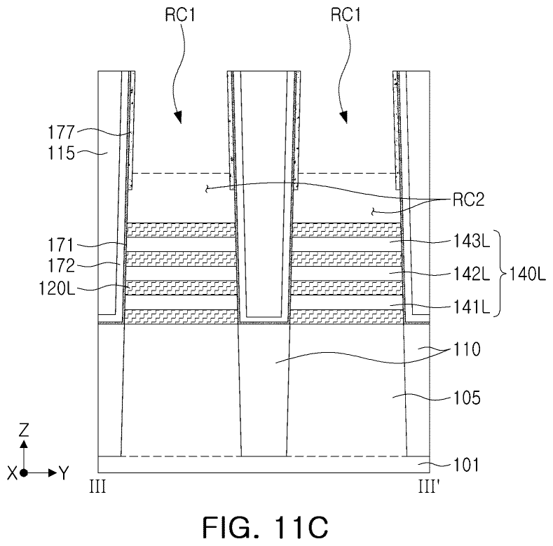

Referring to FIGS. 11A to 11C, through the first recess portion RC1, a second recess portion RC2 exposing the lower stack LS by removing the first buffer layer (140B1 of FIG. 10A) may be formed.

As the second recess portion RC2 is formed, a horizontal portion of the insulating layer 177 may be removed.

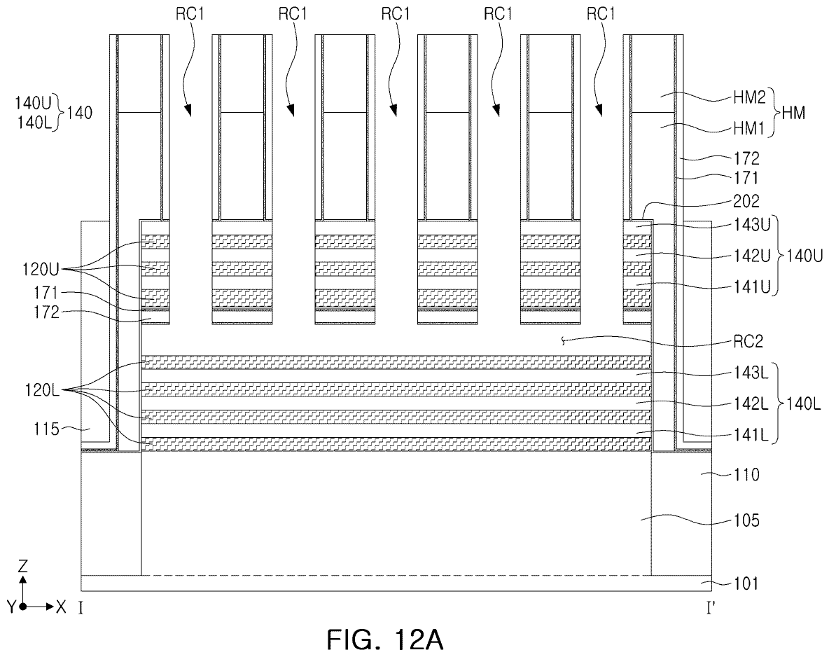

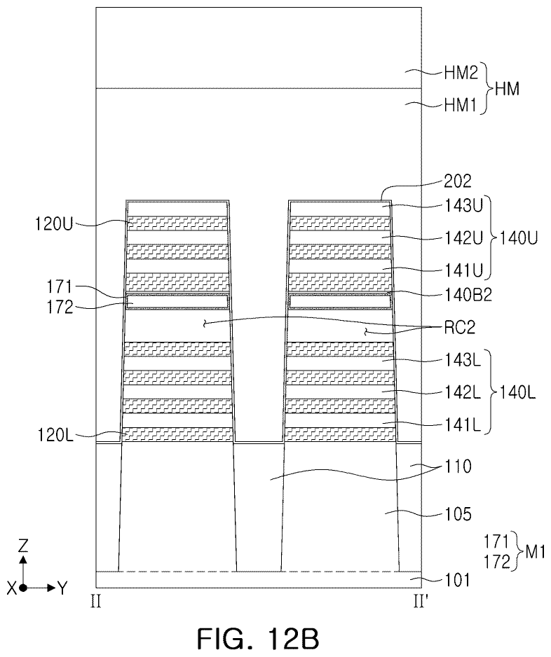

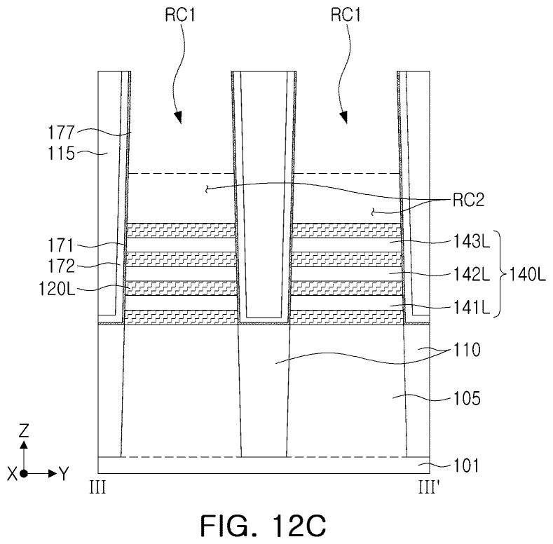

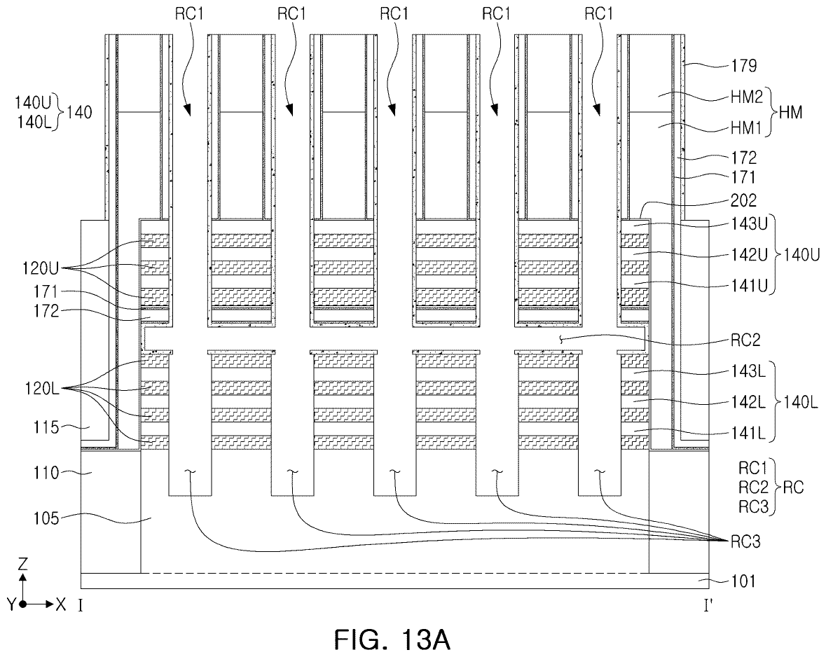

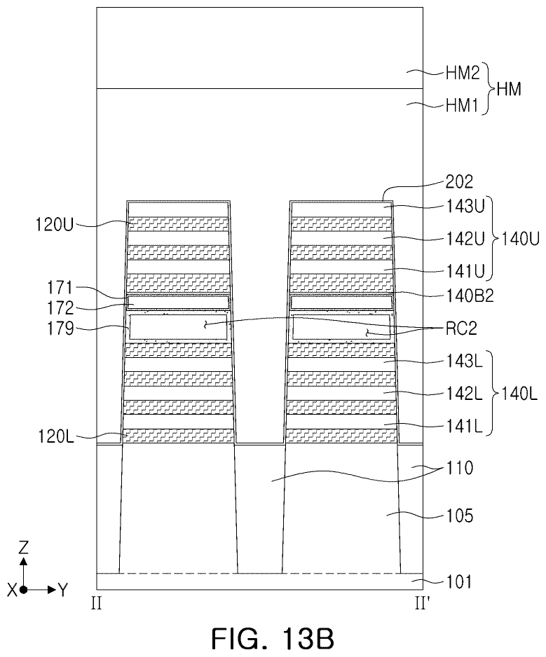

Referring to FIGS. 12A to 12C, the insulating layer (177 of FIG. 11A) may be removed.

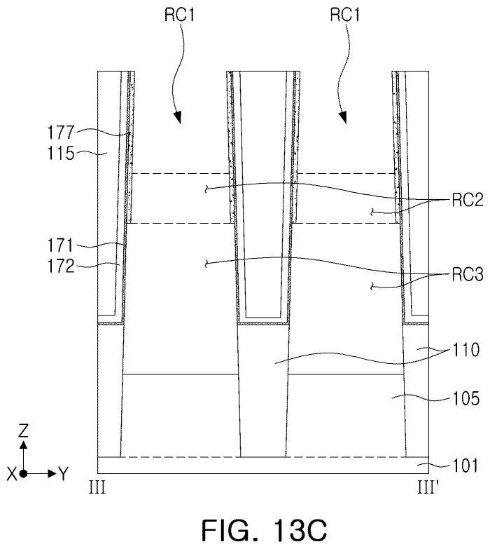

Referring to FIGS. 13A to 13C, an insulating layer 179 covering the surfaces of the first and second recess portions RC1 and RC2 may be formed, and a third recess portion RC3 that penetrates the lower stack LS and the substrate 101 may be formed. The third recess portion RC3 may vertically overlap the first recess portion RC1. In an example embodiment, the first to third recess portions RC1, RC2, and RC3 may be collectively referred to as the recess RC.

As the third recess portion RC3 is formed, a portion of the insulating layer 179 may be removed.

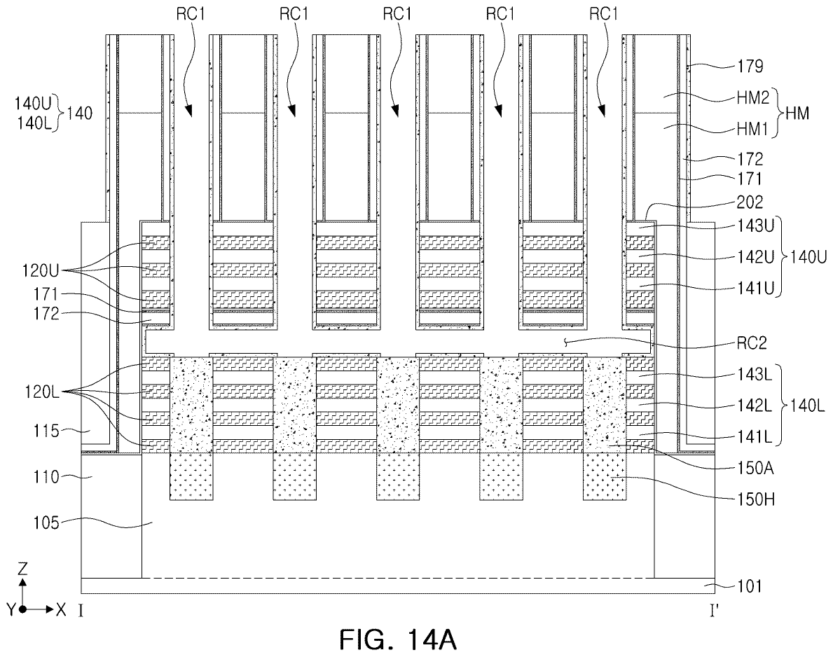

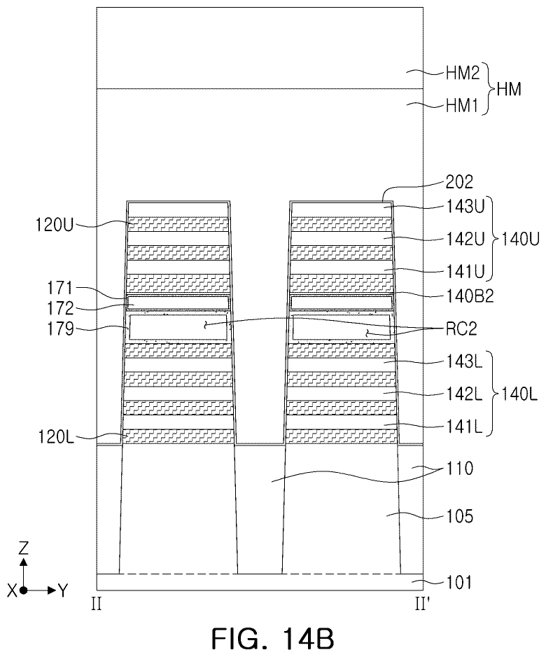

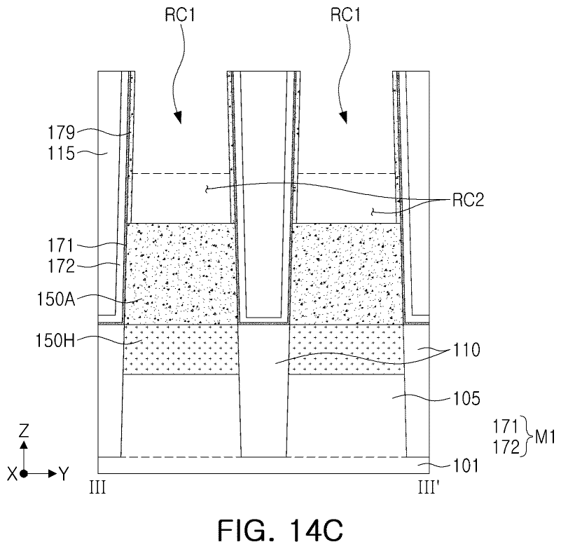

Referring to FIGS. 14A to 14C, an impurity region 150H and a lower source/drain region 150A may be sequentially formed in the third recess portion (RC3 of FIG. 13A).

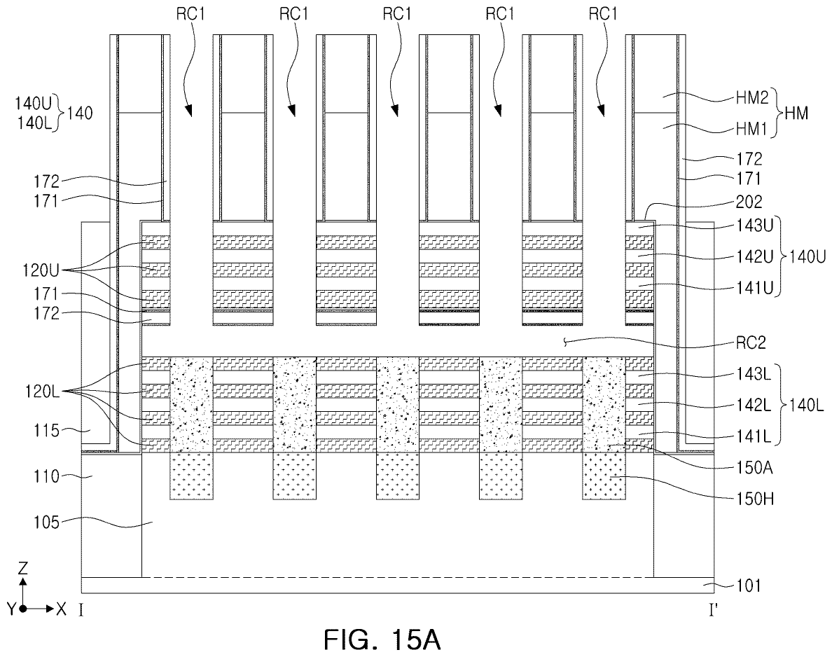

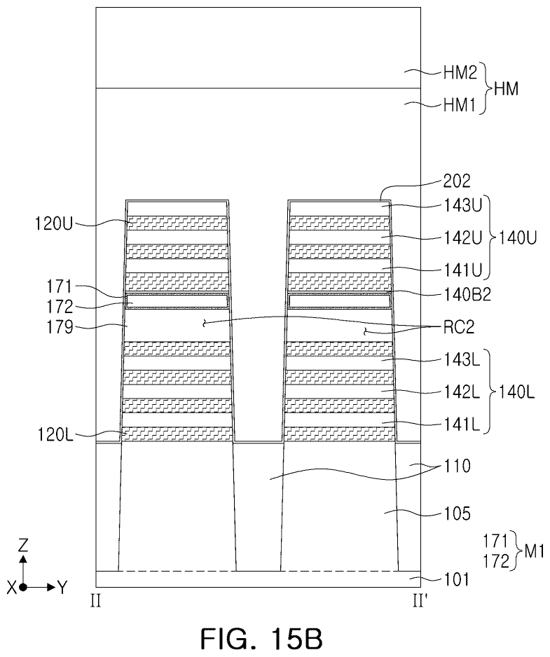

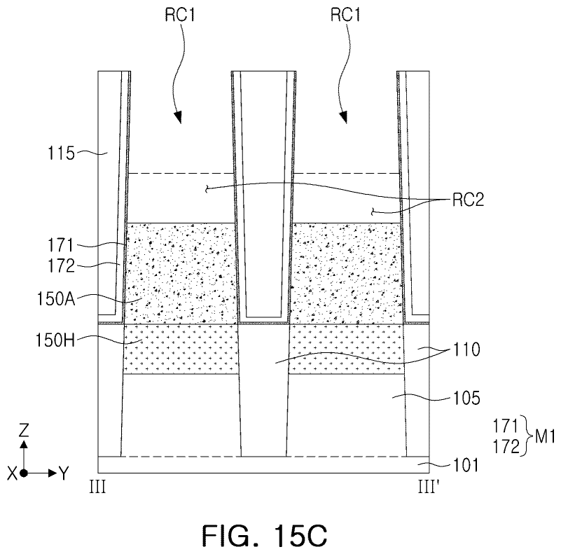

Referring to FIGS. 15A to 15C, the insulating layer (179 of FIG. 14A) may be removed.

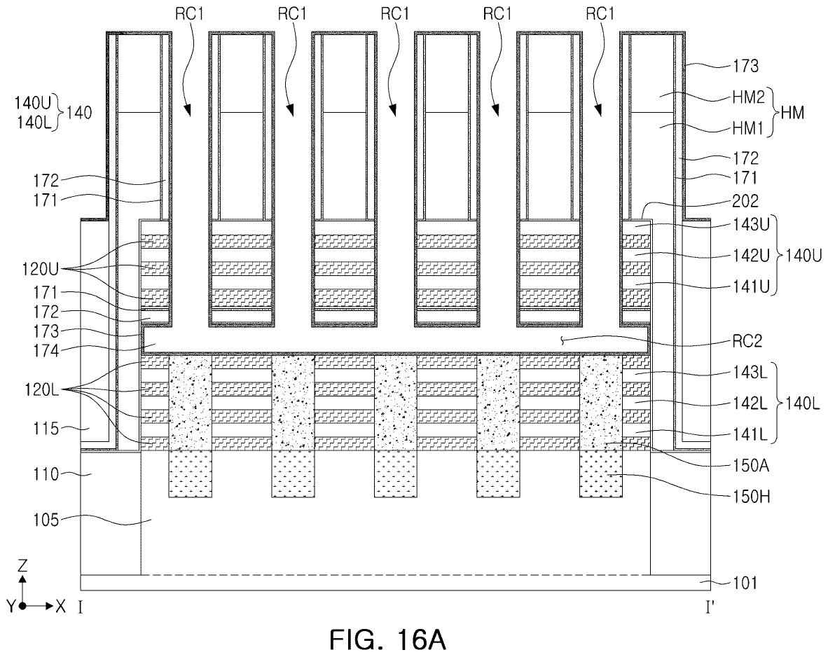

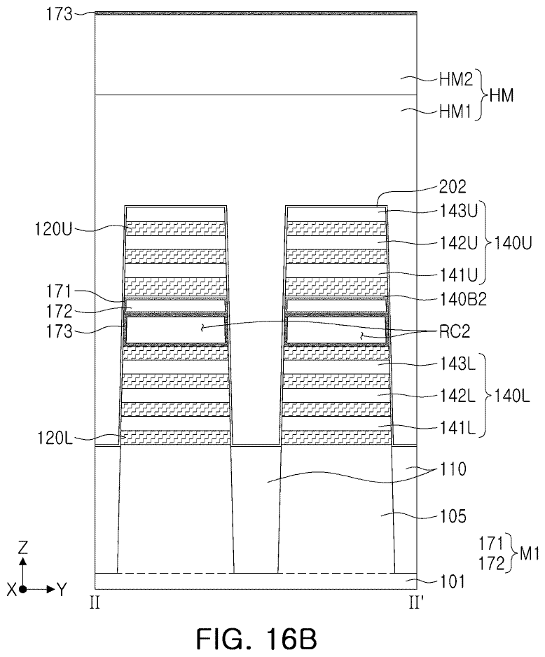

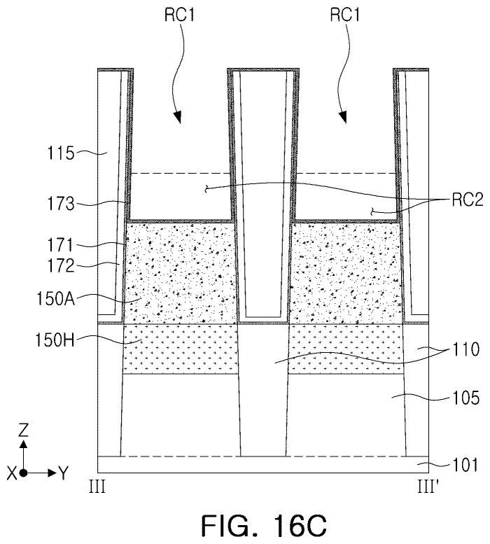

Referring to FIGS. 16A to 16C, a barrier insulating layer 173, covering surfaces of the first and second recess portions RC1 and RC2, may be formed.

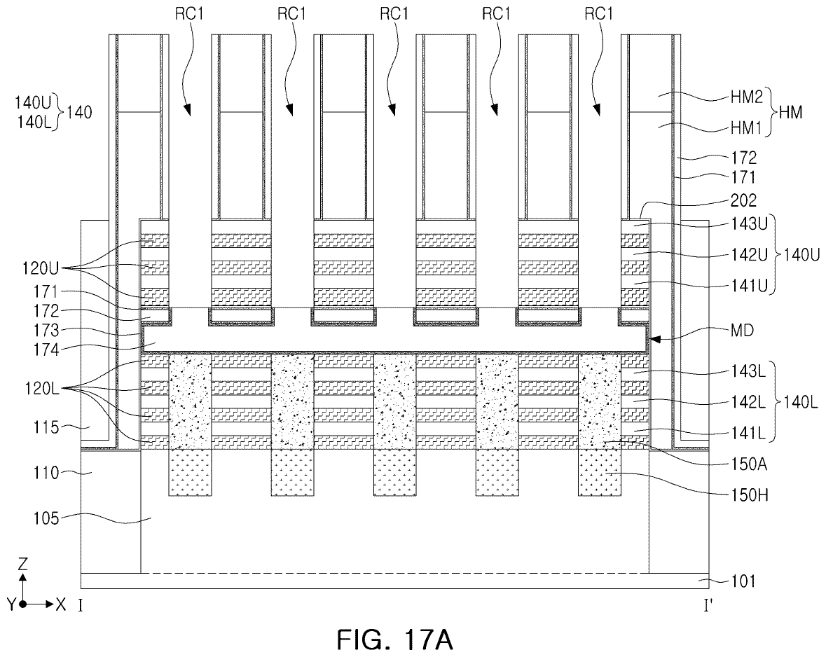

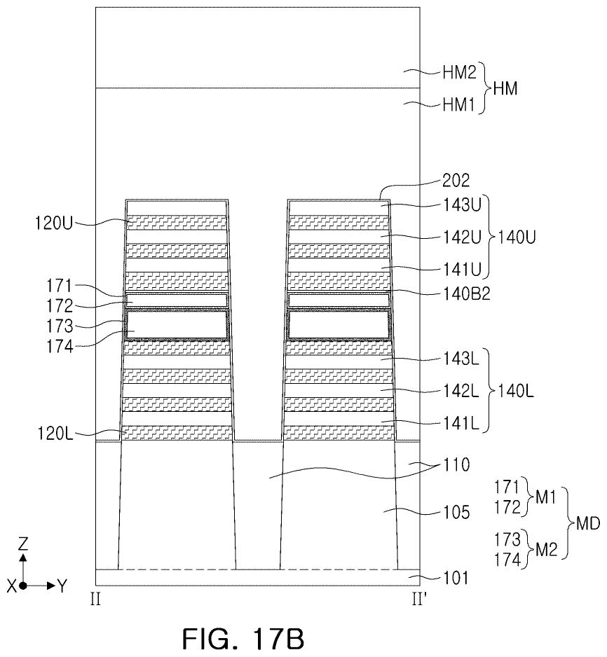

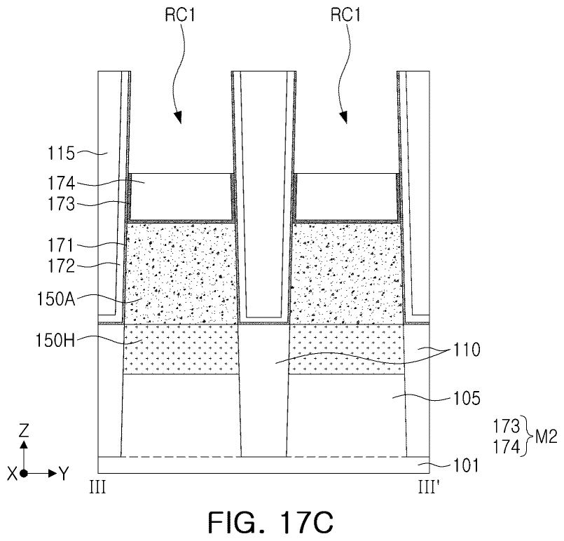

Referring to FIGS. 17A to 17C, an insulating material may be filled in a portion of the first and second recess portions RC1 and RC2, and a barrier pattern 174 may be formed by removing a portion of the barrier insulating layer 173 and a portion of the insulating material.

Accordingly, a barrier structure M2 including the remaining barrier insulating layer 173 and the barrier pattern 174 may be defined.

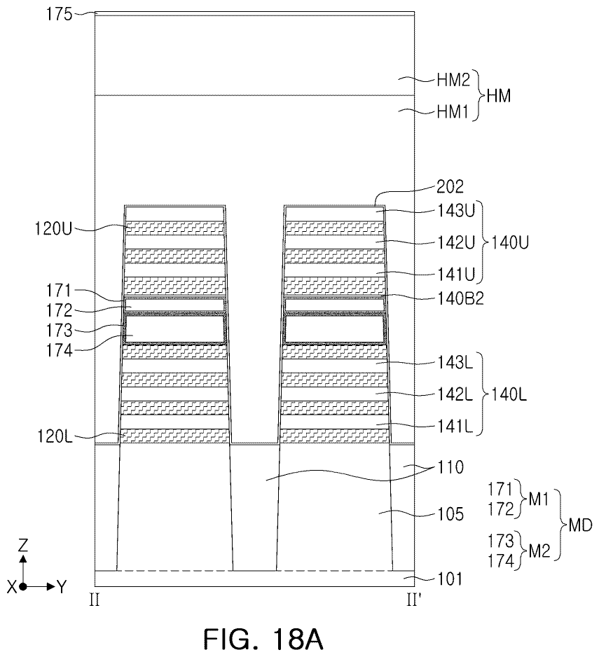

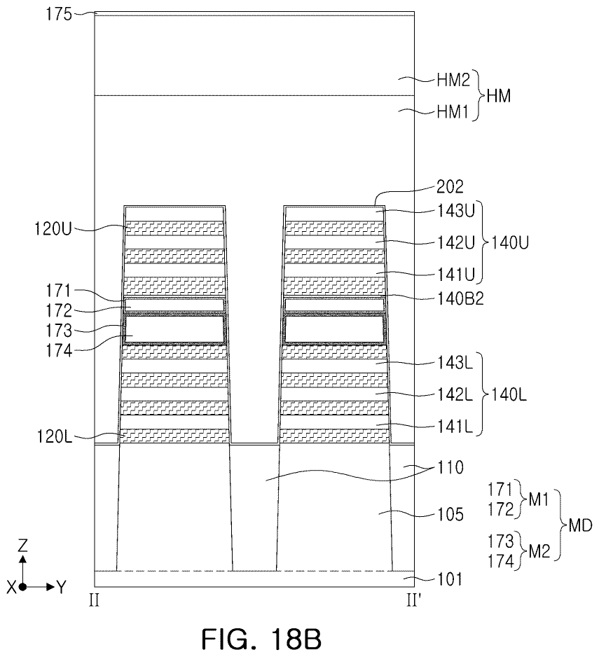

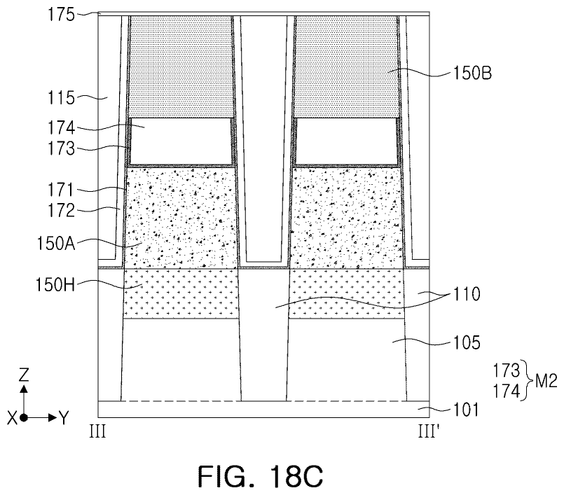

Referring to FIGS. 18A to 18C, an upper source/drain region 150B may be formed in the first recess portion (RC1 of FIG. 17A). Subsequently, an insulating layer 175 covering the upper source/drain region 150B may be conformally formed on the mask HM.

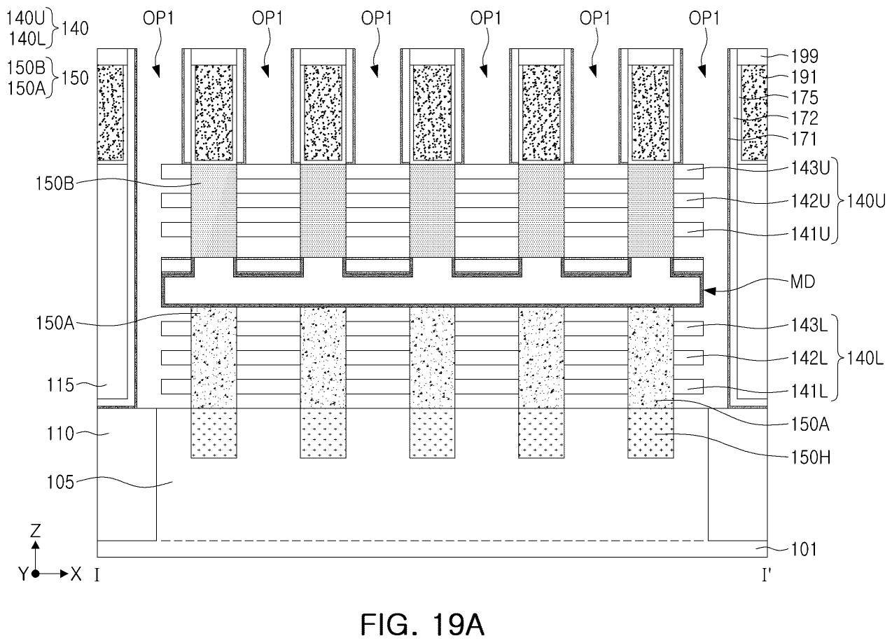

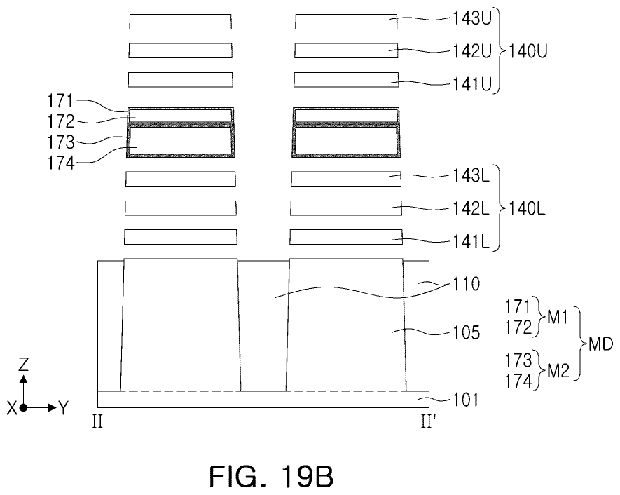

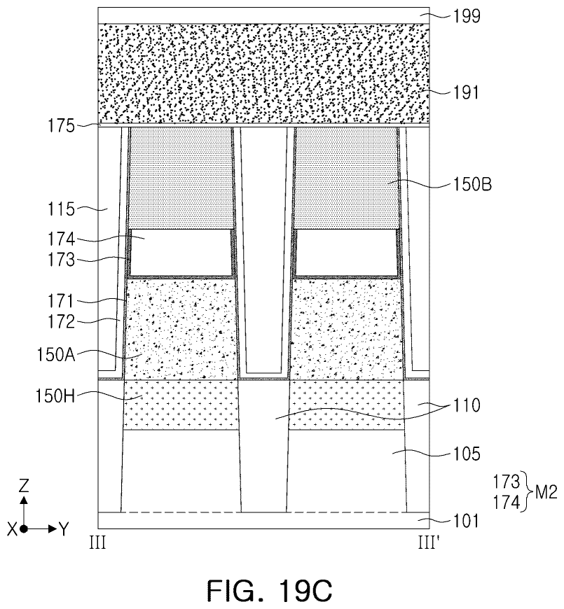

Referring to FIGS. 19A to 19C, insulating layers 191 and 199 may be formed in the open region (OR of FIG. 18A) defined between the masks HM, and the masks HM may be removed. Accordingly, a plurality of open portions OP1, exposing a plurality of channel layers 140, may be defined. The insulating layer 191 may include silicon oxide, and the insulating layer 199 may include silicon nitride.

As the masks HM are removed, the upper and lower sacrificial layers (120U and 120L of FIG. 18A) may be exposed, and the exposed upper and lower sacrificial layers (120U and 120L of FIG. 18A) may be removed using etching selectivity.

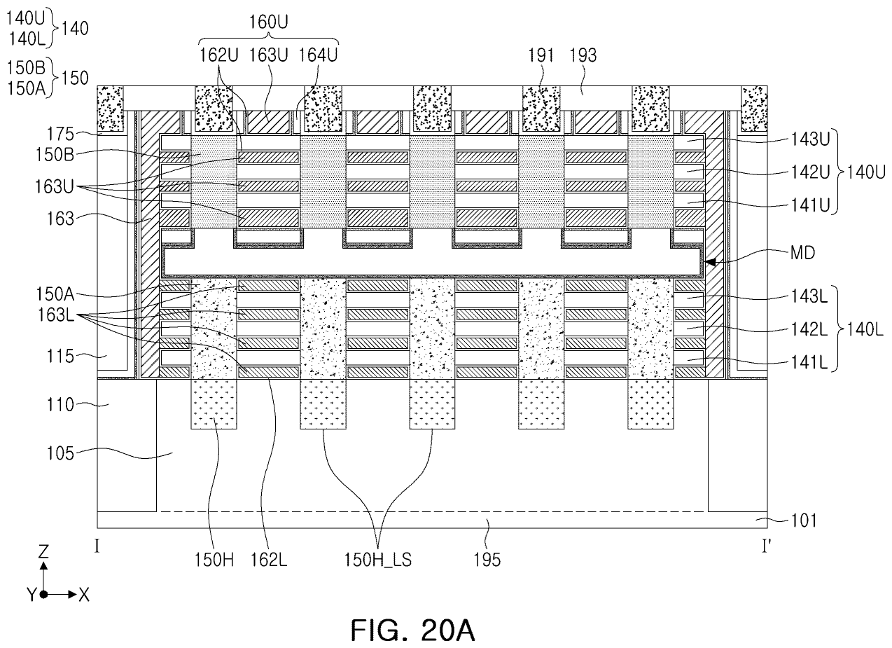

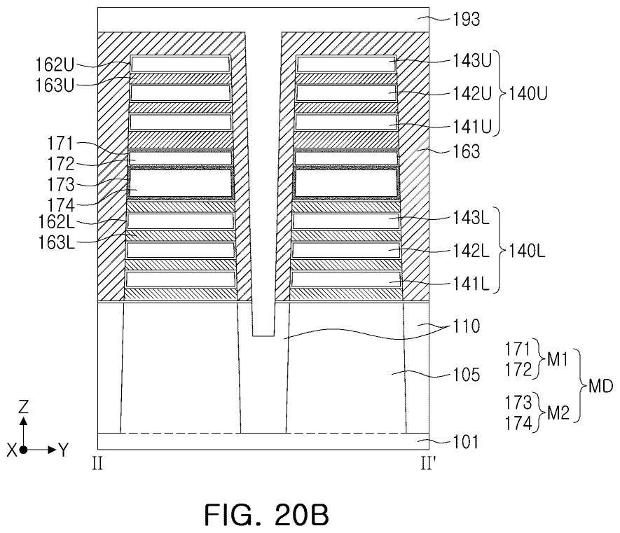

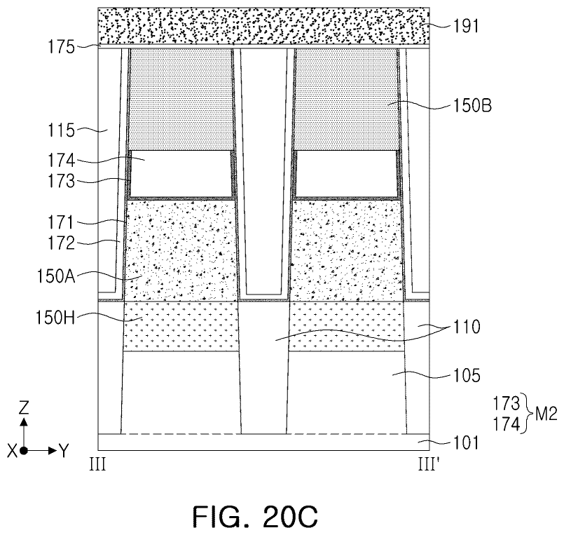

Referring to FIGS. 20A to 20C, a dielectric layer 162U may be formed by depositing an insulating material on surfaces of the plurality of open portions OP1, and a gate electrode 163 may be formed by filling a conductive material in the plurality of open portions OP1. In an example embodiment, a gate electrode below the upper channel layers 141U, 142U, and 143U may be referred to as an upper gate electrode 163U, and a gate electrode above the lower channel layers 141L, 142L, and 143L may be referred to as a lower gate electrode 163L.

In an example embodiment, the upper gate electrode 163U may include an N-type work function layer. Specifically, the upper gate electrode 163U below the upper channel layers 141U, 142U, and 143U may include an N-type work function layer. An upper gate structure 160U including the upper gate dielectric layer 162U, the upper gate electrode 163U, and the upper gate spacer layer 164U may be defined.

In an example embodiment, the lower gate electrode 163L may include a P-type work function layer. Specifically, the lower gate electrode 163L above the lower channel layers 141L, 142L, and 143L may include an P-type work function layer.

Subsequently, a remaining portion of the plurality of open portions OP1 may be filled with an insulating material to form an insulating layer 193. A portion of the insulating layer 193 may pass through the gate electrode 163 and extend into the isolation layer 110.

A portion of the insulating layers (191 and 199 of FIG. 19A) may be removed to expose upper surfaces of the insulating layers 191 and 193. The insulating layer 193 may include silicon nitride.

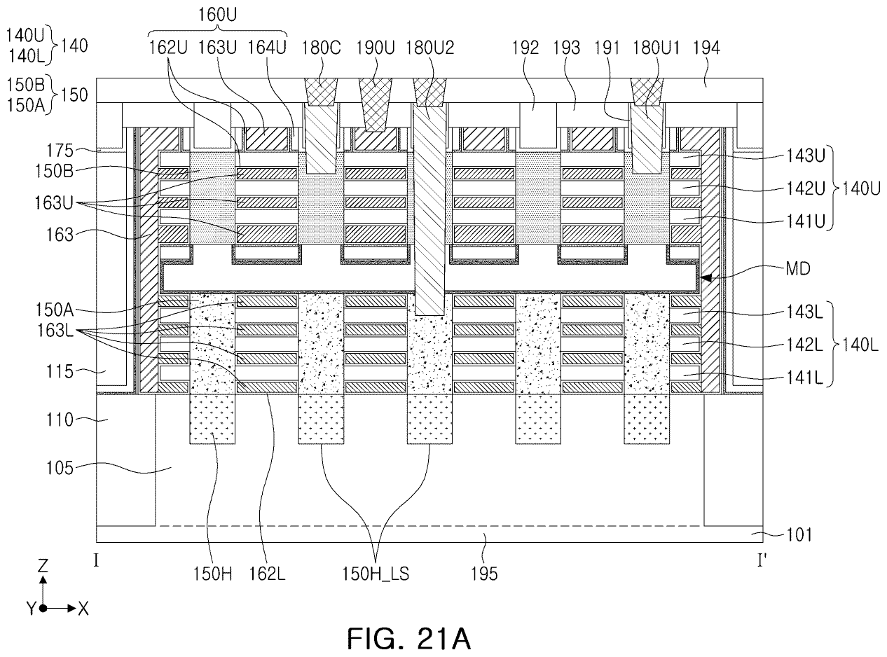

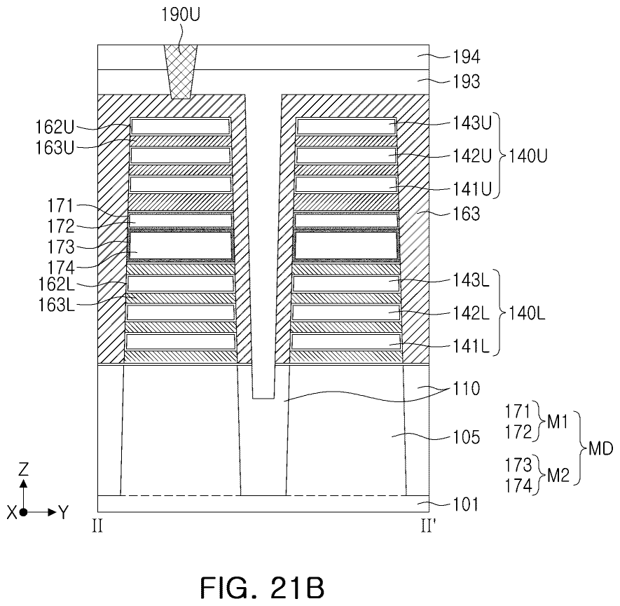

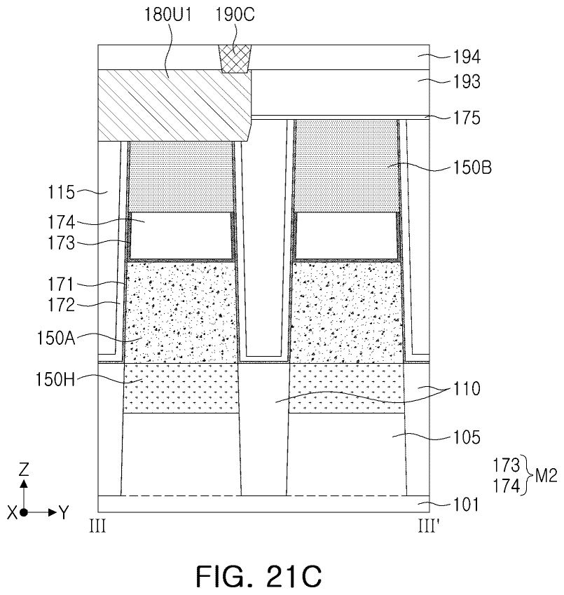

Referring to FIGS. 21A to 21C, an upper contact structure 180U and an upper gate contact structure 190U may be formed.

A first upper contact structure 180U1 passing through the insulating layers 191 and 175, the first upper contact structure 180U1 in contact with the upper source/drain region 150B may be formed. A second upper contact structure 180U2 passing through the insulating layers 191 and 175 and the upper source/drain region 150B, the second upper contact structure 180U2 in contact with the lower source/drain region 150A may be formed.

Subsequently, an insulating layer 194 covering the upper contact structure 180U may be formed, and a contact via structure 180C passing through the insulating layer 194, the contact via structure 180C connected to the upper contact structure 180U, and an upper gate contact structure 190U passing through the insulating layers 193 and 194, the upper gate contact structure 190U connected to the upper gate electrode 163U may be formed.

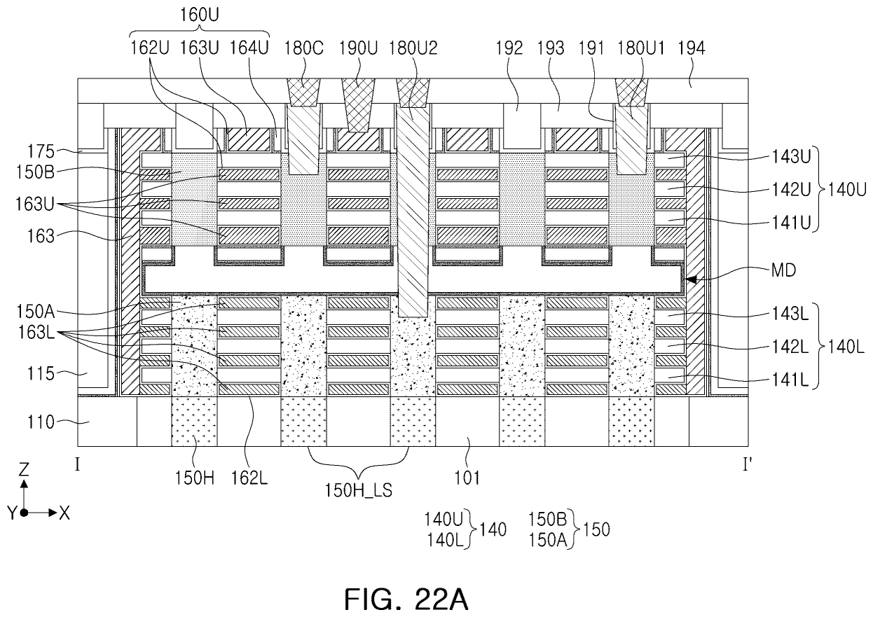

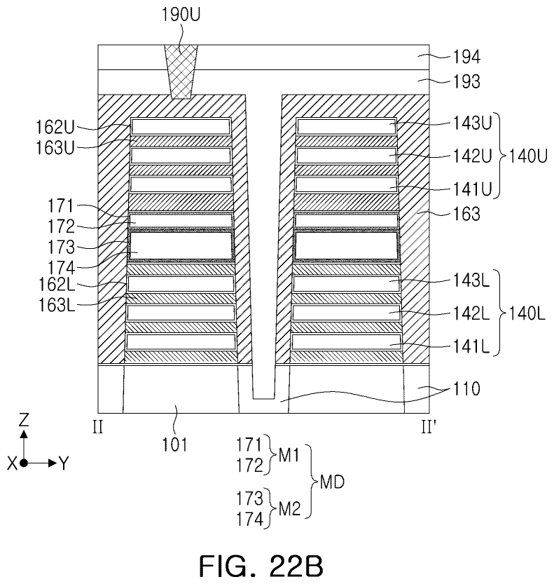

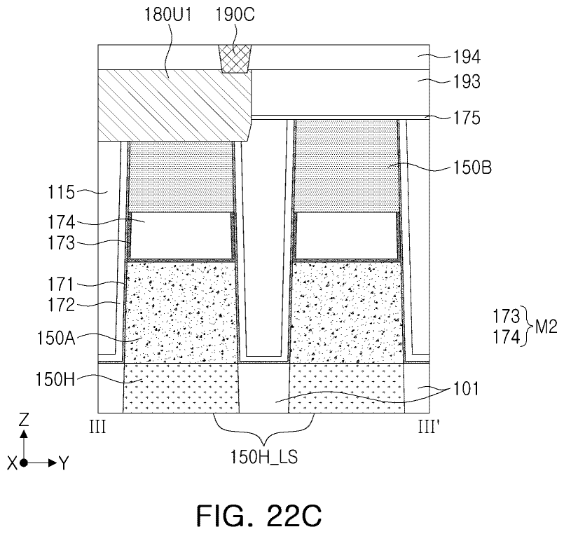

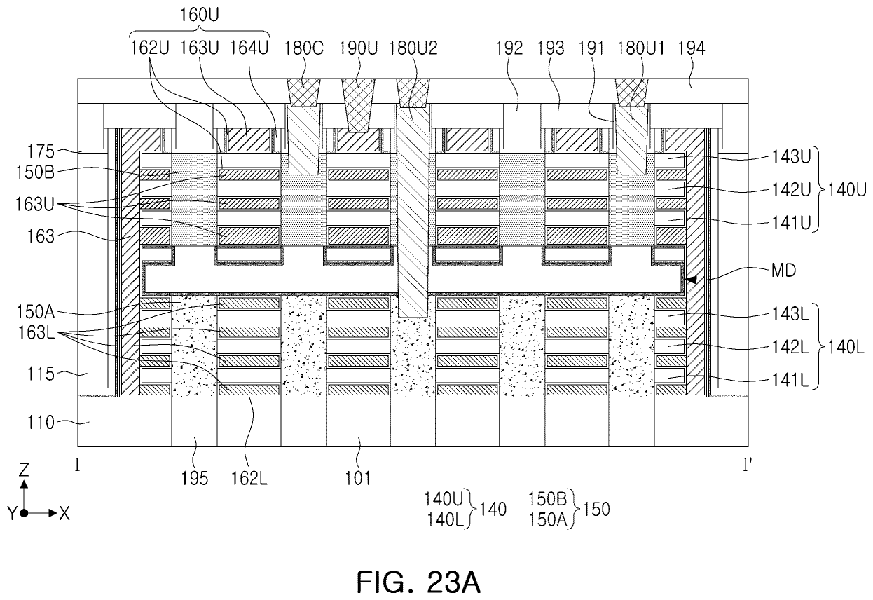

Referring to FIGS. 22A to 22C, a lower region of the substrate 101 may be removed to expose a lower surface 150H_LS of the impurity region 150H.

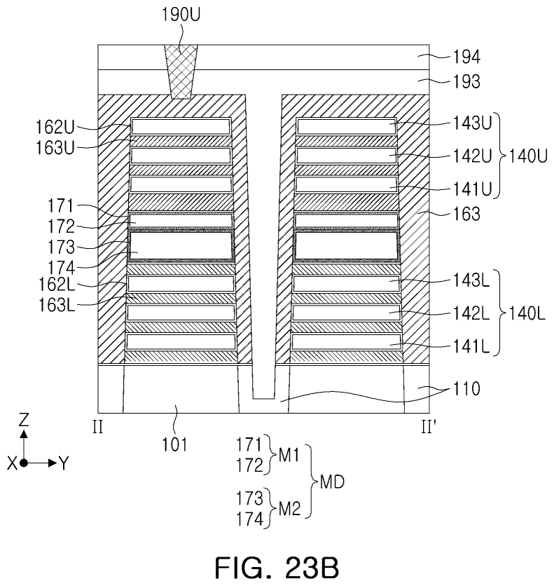

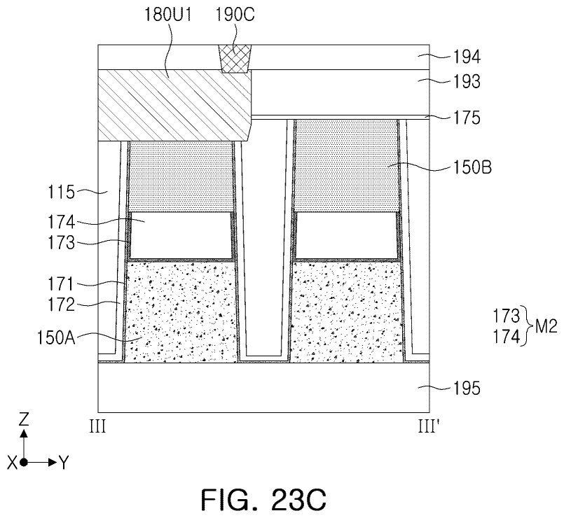

Referring to FIGS. 23A to 23C, an insulating layer 195 may be formed by removing the impurity region 150H and filling an insulating material.

The insulating layer 195 may include silicon oxide.

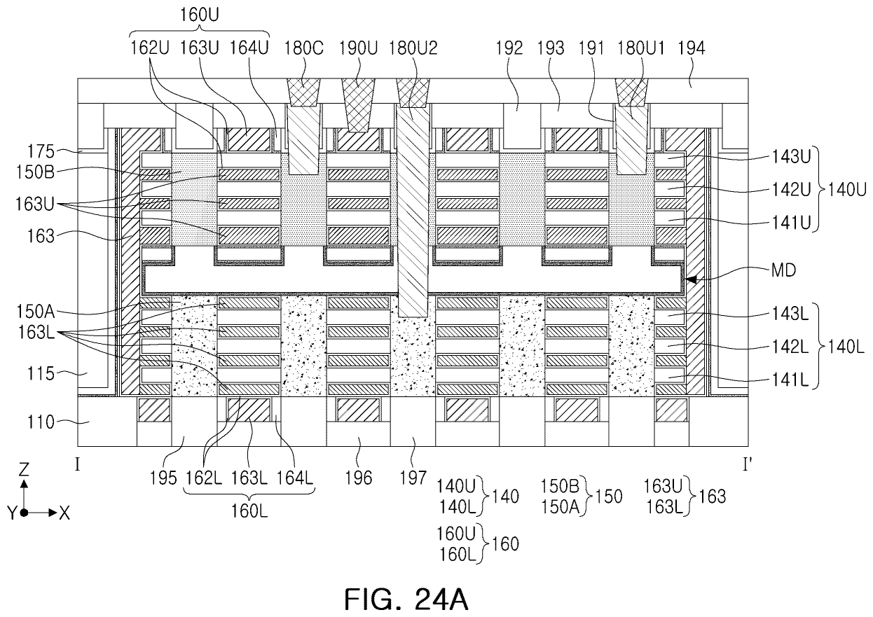

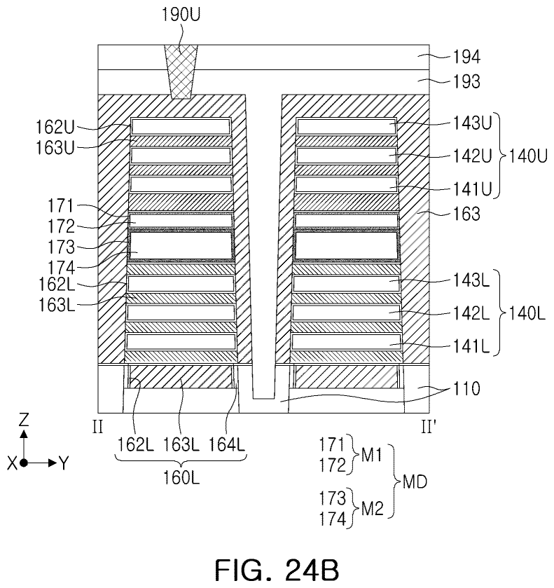

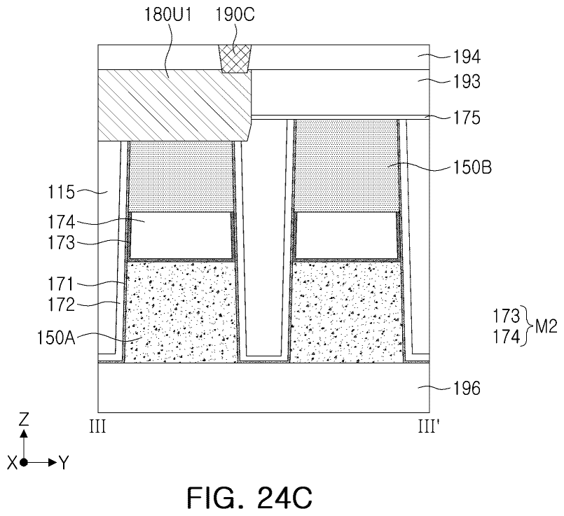

Referring to FIGS. 24A to 24C, a lowermost lower gate structure 160L may be formed.

The substrate (101 of FIG. 23A) may be removed to expose a lower surface of a lower gate dielectric layer 162L. Subsequently, a lower gate spacer layer 164L, a lower gate dielectric layer 162L, and a lower gate electrode 163L may be formed to form a lowermost lower gate structure 160L. Subsequently, an insulating layer 196, covering the lowermost lower gate structure 160L, may be formed.

Subsequently, referring back to FIG. 2A, a lower contact structure 180L and a lower gate contact structure 190L may be formed.

A lower contact structure 180L passing through the insulating layers 195, the lower contact structure 180L in contact with the lower source/drain region 150A may be formed.

Subsequently, an insulating layer 198, covering the lower contact structure 180L, may be formed, a contact via structure 180C passing through the insulating layer 198, the contact via structure 180C connected to the lower contact structure 180L, and a lower gate contact structure 190L passing through the insulating layers 198 and 196, the lower gate contact structure 190L connected to the lower gate electrode 163L may be formed.

According to example embodiments of the present inventive concept, a semiconductor device having improved reliability and improved performance and a method of manufacturing the same may be provided.

Specifically, according to example embodiments of the present inventive concept, a semiconductor device including an intermediate insulating structure having a predetermined thickness or less may be provided.

According to another aspect of the present inventive concept, there is provided a method of manufacturing a semiconductor device, the method including sequentially forming, on a substrate, a lower stack in which lower sacrificial layers and lower channel layers are alternately stacked, an intermediate stack in which a first buffer layer, an intermediate sacrificial layer, and a second buffer layer are sequentially stacked, and an upper stack in which upper sacrificial layers and upper channel layers are alternately stacked, removing the intermediate sacrificial layer of the intermediate stack and forming a preliminary insulating structure including an insulating liner and an insulating pattern, sequentially forming a first recess portion passing through the upper stack and the preliminary insulating structure and exposing the first buffer layer, a second recess portion removing the first buffer layer and exposing the lower stack, and a third recess portion passing through the lower stack and the substrate-an insulating structure being defined from the preliminary insulating structure by forming the first recess portion, and the third recess portion vertically overlapping the first recess portion, forming a lower source/drain region in the third recess portion, forming a barrier structure including a barrier insulating layer and a barrier pattern in the second recess portion, and forming an upper source/drain region in the first recess portion.

A germanium concentration of the intermediate sacrificial layer may be greater than germanium concentrations of the lower channel layers and the upper channel layers.

A thickness of the intermediate sacrificial layer may be in a range of about 5 nm to about 10 nm.

A thickness of the first buffer layer may be less than a thickness of each of the upper sacrificial layers, and a thickness of the second buffer layer may be greater than a thickness of each of the lower sacrificial layers.

The insulating liner may cover an upper surface and a lower surface of the insulating pattern, and may surround at least a portion of a side surface of the insulating pattern.

The barrier insulating layer may cover an upper surface of the lower stack and a lower surface and a side surface of the insulating structure, and may surround at least a portion of the barrier pattern.

At least a portion of an upper surface of the barrier pattern may be in contact with a lower surface of the upper source/drain region.

The insulating liner may include silicon nitride, and the insulating pattern may include silicon oxycarbonitride.

The barrier insulating layer may include silicon nitride, and the barrier pattern may include silicon oxide.

The method may further include removing the upper and lower sacrificial layers and forming a gate structure.

While example embodiments have been shown and described above, it will be apparent to those skilled in the art that modifications and variations could be made without departing from the scope of the present disclosure as defined by the appended claims.

What is claimed is:

1. A semiconductor device comprising:
a lower structure;
an upper structure; and
an intermediate insulating structure between the lower structure and the upper structure, wherein the lower structure includes:
lower source/drain regions spaced apart from each other in a first direction;
lower active layers spaced apart from each other in a vertical direction, the lower active layers disposed between the lower source/drain regions, the lower active layers connected to the lower source/drain regions; and
a lower gate structure extending in a second direction, perpendicular to the first direction, the lower gate structure including portions respectively disposed above the lower active layers,
the upper structure includes:
upper source/drain regions spaced apart from each other in the first direction, the upper source/drain regions vertically overlapping the lower source/drain regions;
upper active layers spaced apart from each other in the vertical direction, the upper active layers disposed between the upper source/drain regions and connected to the upper source/drain regions, the upper active layers vertically overlapping the lower active layers; and
an upper gate structure extending in the second direction, the upper gate structure including portions respectively disposed below the upper active layers, the upper gate structure vertically overlapping the lower gate structure, and the intermediate insulating structure includes:
an insulating structure below the upper structure; and
a barrier structure including a barrier insulating layer on the lower structure and a barrier pattern disposed above the barrier insulating layer, the barrier pattern surrounding the insulating structure and in contact with lower surfaces of the upper source/drain regions.

2. The semiconductor device of claim 1, wherein the insulating structure includes:
an insulating liner including an upper portion on a lower surface of the upper structure and a lower portion below the upper portion; and
an insulating pattern between the upper portion and the lower portion of the insulating liner.

3. The semiconductor device of claim 1, wherein a side surface of the insulating structure has a concave shape toward a center of the insulating structure.

4. The semiconductor device of claim 2, wherein
the insulating liner includes silicon nitride, and
the insulating pattern includes silicon oxycarbonitride.

5. The semiconductor device of claim 1, wherein a thickness of the insulating structure is in a range of about 5 nm to about 10 nm.

6. The semiconductor device of claim 1, wherein the barrier insulating layer of the barrier structure includes a first portion, extending in the first direction, and disposed on an upper surface of the lower structure.

7. The semiconductor device of claim 6, wherein the barrier insulating layer further includes a second portion disposed between the insulating structure and the barrier pattern, the second portion covering a side surface and a lower surface of the insulating structure.

8. The semiconductor device of claim 7, wherein the second portion of the barrier insulating layer is in contact with the lower surfaces of the upper source/drain regions.

9. The semiconductor device of claim 1, wherein at least a portion of an upper surface of the barrier pattern of the barrier structure has a recessed shape toward the lower structure.

10. The semiconductor device of claim 1, wherein
the barrier insulating layer includes silicon nitride, and
the barrier pattern includes silicon oxide.

11. The semiconductor device of claim 1, wherein the upper source/drain regions and the lower source/drain regions have different conductivity types.

12. The semiconductor device of claim 1, further comprising:
a first upper contact structure disposed on a first upper source/drain region among the upper source/drain regions, the first upper contact structure connected to the first upper source/drain region; and
a lower contact structure disposed below the lower source/drain regions, the lower contact structure connected to the lower source/drain regions.

13. The semiconductor device of claim 12, further comprising:
a second upper contact structure disposed on a second upper source/drain region among the upper source/drain regions, the second upper contact structure passing through the second upper source/drain region and the barrier structure and connected to the lower source/drain regions.

14. The semiconductor device of claim 12, further comprising:
an upper gate contact structure disposed on the upper gate structure, the upper gate contact structure electrically connected to an upper gate electrode of the upper gate structure; and
a lower gate contact structure disposed below the lower gate structure, the lower gate contact structure electrically connected to a lower gate electrode of the lower gate structure.

15. A semiconductor device comprising:
a first structure;
a barrier structure on the first structure;
an insulating structure on the barrier structure; and
a second structure on the insulating structure,
wherein the first structure includes:
first source/drain regions spaced apart from each other in a first direction;
first active layers spaced apart from each other in a vertical direction, the first active layers disposed between the first source/drain regions, the first active layers connected to the first source/drain regions; and
a first gate structure extending in a second direction, perpendicular to the first direction, the first gate structure including portions respectively disposed above the first active layers,
the second structure includes:
second source/drain regions spaced apart from each other in the first direction, the second source/drain regions vertically overlapping the first source/drain regions;
second active layers spaced apart from each other in the vertical direction, the second active layers disposed between the second source/drain regions and connected to the second source/drain regions, the second active layers vertically overlapping the first active layers; and
a second gate structure extending in the second direction, the second gate structure including portions respectively disposed below the second active layers, the second gate structure vertically overlapping the first gate structure, the barrier structure includes:
a barrier pattern; and
a barrier insulating layer surrounding the barrier pattern, on the first structure, and
the insulating structure includes:
an insulating pattern; and
an insulating liner surrounding the insulating pattern, on the barrier structure.

16. The semiconductor device of claim 15, wherein
the barrier insulating layer surrounds a lower surface, a side surface, and an upper surface of the barrier pattern,
the insulating liner surrounds a lower surface, a side surface, and an upper surface of the insulating pattern, and
an upper surface of the barrier insulating layer and a lower surface of the insulating liner are in contact with each other.

17. The semiconductor device of claim 15, wherein a thickness of the barrier insulating layer is greater than a thickness of the insulating liner.

18. The semiconductor device of claim 15, wherein a width of the insulating pattern in the second direction is greater than a width of the barrier pattern in the second direction.

19. A semiconductor device comprising:
a lower structure;
an upper structure; and
an intermediate insulating structure between the lower structure and the upper structure, wherein the lower structure includes:
lower source/drain regions spaced apart from each other in a first direction;
lower active layers spaced apart from each other in a vertical direction, the lower active layers disposed between the lower source/drain regions and connected to the lower source/drain regions; and
a lower gate structure extending in a second direction, perpendicular to the first direction, the lower gate structure including portions respectively disposed above the lower active layers,
the upper structure includes:
upper source/drain regions spaced apart from each other in the first direction, the upper source/drain regions vertically overlapping the lower source/drain regions;
upper active layers spaced apart from each other in the vertical direction, the upper active layers disposed between the upper source/drain regions and connected to the upper source/drain regions, the upper active layers vertically overlapping the lower active layers; and
an upper gate structure extending in the second direction, the upper gate structure including portions respectively disposed below the upper active layers, the upper gate structure vertically overlapping the lower gate structure, the intermediate insulating structure includes:
a barrier structure disposed on the lower structure, the barrier structure including a barrier pattern and a barrier insulating layer surrounding the barrier pattern; and
an insulating structure disposed between the barrier structure and the upper structure, the insulating structure including an insulating pattern and an insulating liner surrounding the insulating pattern, and
a thickness of the barrier structure is greater than a thickness of the insulating structure.

20. The semiconductor device of claim 19, further comprising:
a first insulating layer between the lower structure and the barrier structure; and
a second insulating layer between the upper structure and the insulating structure.
